(19) United States
(12) Patent Application Publication
(10) Pub. No.: US 2026/0006951 A1
(43) Pub. Date: Jan. 1, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: Ki Chang EOM, Yongin-si (KR); Kyung Rock SON, Yongin-si (KR); Hui Won YANG, Yongin-si (KR); Jae Phil LEE, Yongin-si (KR)

(73) Assignee: Samsung Display Co., LTD., Yongin-si (KR)

(21) Appl. No.: 19/223,858

(22) Filed: May 30, 2025

(30) Foreign Application Priority Data
Jun. 28, 2024 (KR) 10-2024-0085488

(51) Int. Cl. H10H 20/831; G02B 27/01; H01L 25/16; H10H 20/01; H10H 20/813; H10H 20/857

(52) U.S. Cl. CPC H10H 20/8312; G02B 27/0172; H01L 25/167; H10H 20/032; H10H 20/8131; H10H 20/857; G02B 2027/0178

(57) ABSTRACT

A display device includes a cathode disposed on a pixel circuit layer, a first anode, a first light-emitting element including a first emission stack, a first anode connection electrode, a first cathode connection electrode, an adhesive layer disposed between the first anode and the first anode connection electrode and between the cathode and the first cathode connection electrode, a first anode bridge electrode in contact with the first anode and the first anode connection electrode, and a cathode bridge electrode in contact with the cathode and the first cathode connection electrode. A planarization layer forming an uppermost layer of the pixel circuit layer includes a first anode undercut formed along an edge of the first anode between the planarization layer and a lower surface of the first anode, and a cathode undercut formed along an edge of the cathode between the planarization layer and a lower surface of the cathode.

### CROSS-REFERENCE TO RELATED APPLICATION

This application claims priority to and benefits of Korean Patent Application No. 10-2024-0085488 under 35 U.S.C. § 119, filed on Jun. 28, 2024 in the Korean Intellectual Property Office, the entire contents of which are incorporated herein by reference.

### BACKGROUND

### 1. Technical Field

The disclosure relates to a display device, a method of manufacturing the display device, and an electronic device including the display device.

### 2. Description of the Related Art

A display device includes pixels, and each of the pixels includes a light-emitting element that emits light independently. A display device may display an image by combining light of different colors emitted from the pixels.

Users of display devices that use ultra-small light-emitting diodes (LEDs) (for example, micro-LEDs) as light-emitting elements have been increasing and becoming more popular.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device with improved reliability.

Embodiments also provide a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

A display device according to embodiments includes a cathode disposed on a pixel circuit layer and extending in a first direction, a first anode disposed on the pixel circuit layer and spaced apart from the cathode in a second direction intersecting the first direction, a first light-emitting element including a first emission stack, a first anode connection electrode electrically connected to one area of the first emission stack, and a first cathode connection electrode electrically connected to another area of the first emission stack, an adhesive layer disposed between the first anode and the first anode connection electrode and between the cathode and the first cathode connection electrode, a first anode bridge electrode in direct contact with the first anode and the first anode connection electrode, and a cathode bridge electrode in direct contact with the cathode and the first cathode connection electrode. A planarization layer forming an uppermost layer of the pixel circuit layer includes a first anode undercut formed along an edge of the first anode in a plan view between the planarization layer and a lower surface of the first anode, and a cathode undercut formed along an edge of the cathode in a plan view between the planarization layer and a lower surface of the cathode.

In an embodiment, the adhesive layer may completely cover a side surface facing the first anode among side surfaces of the cathode.

In an embodiment, the adhesive layer may expose another side surface opposite to the side surface among the side surfaces of the cathode.

In an embodiment, the adhesive layer may cover an upper surface of the cathode adjacent to the side surface of the cathode and may expose an upper surface of the cathode adjacent to the another side surface of the cathode.

In an embodiment, the cathode bridge electrode may be in direct contact with the upper surface of the cathode adjacent to the another side surface of the cathode.

In an embodiment, the display device may further include a second anode disposed on the pixel circuit layer, spaced apart from the cathode in the second direction, and spaced apart from the first anode in the first direction, a second light-emitting element including a second emission stack, a second anode connection electrode electrically connected to an area of the second emission stack, and a second cathode connection electrode electrically connected to another area of the second emission stack, and a second anode bridge electrode in direct contact with the second anode and the second anode connection electrode, wherein the planarization layer further includes a second anode undercut formed along an edge of the second anode in a plan view between the planarization layer and a lower surface of the second anode.

In an embodiment, the cathode bridge electrode may be in direct contact with the second cathode connection electrode.

In an embodiment, the adhesive layer may expose a side surface facing the second anode among side surfaces of the first anode.

In an embodiment, the first anode bridge electrode may be in direct contact with at least a portion of the side surface of the first anode.

In an embodiment, the adhesive layer may expose another side surface opposite to the side surface among the side surfaces of the first anode.

In an embodiment, the first anode bridge electrode may be in direct contact with at least a portion of the another side surface of the first anode.

In an embodiment, the adhesive layer may expose a side surface facing the first anode among side surfaces of the second anode.

In an embodiment, the second anode bridge electrode may be in direct contact with at least a portion of the side surface of the second anode.

In an embodiment, the adhesive layer may expose another side surface opposite to the side surface among the side surfaces of the second anode.

In an embodiment, the second anode bridge electrode may be in direct contact with at least a portion of the another side surface of the second anode.

In an embodiment, a method of manufacturing a display device according to embodiments includes forming a cathode and a first anode, which are spaced apart from each other, on a planarization layer forming an uppermost layer of a pixel circuit layer, forming a first anode undercut and a cathode undercut in the planarization layer, forming an adhesive layer on the first anode and the cathode, arranging a first light-emitting element on the adhesive layer, the first light-emitting element including a first emission stack, a first anode connection electrode electrically connected to an area of the first emission stack and a first cathode connection electrode electrically connected to another area of the first emission stack, and forming a bridge electrode including a first anode bridge electrode electrically connecting the first anode and the first anode connection electrode and a cathode bridge electrode electrically connecting the cathode and the first cathode connection electrode. The first anode undercut is formed along an edge of the first anode in a plan view between the planarization layer and a lower surface of the first anode, and the cathode undercut is formed along an edge of the cathode in a plan view between the planarization layer and a lower surface of the cathode.

In an embodiment, the forming of the first anode undercut and the cathode undercut in the planarization layer may include ashing the planarization layer using the first anode and the cathode as a mask.

In an embodiment, the forming of the bridge electrode may include depositing a bridge electrode layer on upper surfaces of the first light-emitting element, the adhesive layer, the cathode, and the first anode, forming a photoresist pattern layer corresponding to a shape of the first anode bridge electrode and a shape of the cathode bridge electrode, etching the bridge electrode layer using the photoresist pattern layer as a mask, and removing the photoresist pattern layer.

In an embodiment, at least a portion of the bridge electrode layer may be electrically disconnected by the first anode undercut and the cathode undercut.

In an embodiment, the first light-emitting element may partially protrude above the photoresist pattern layer.

In an embodiment, an electronic apparatus includes a processor to provide image data; and a display device to display an image based on the image data. The display device comprises a cathode disposed on a pixel circuit layer and extending in a first direction; a first anode disposed on the pixel circuit layer and spaced apart from the cathode in a second direction intersecting the first direction; a first light-emitting element including a first emission stack, a first anode connection electrode electrically connected to an area of the first emission stack, and a first cathode connection electrode electrically connected to another area of the first emission stack; an adhesive layer disposed between the first anode and the first anode connection electrode and between the cathode and the first cathode connection electrode; a first anode bridge electrode in direct contact with the first anode and the first anode connection electrode; and a cathode bridge electrode in direct contact with the cathode and the first cathode connection electrode. A planarization layer forming an uppermost layer of the pixel circuit layer includes a first anode undercut formed along an edge of the first anode in a plan view between the planarization layer and a lower surface of the first anode; and a cathode undercut formed along an edge of the cathode in a plan view between the planarization layer and a lower surface of the cathode.

The electronic device may be at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a tablet computer, a phablet, a personal digital assistant (PDA), a wearable device, a laptop computer, a digital camera, a camcorder, a viewfinder, a micro display, a three-dimensional (3D) display, a vehicle, a video wall with multiple displays tiled together, a theater screen, a stadium screen, a phototherapy device, and a signboard.

### BRIEF DESCRIPTION OF THE DRAWINGS

An additional appreciation according to the embodiments of the disclosure will become more apparent by describing in detail the elements thereof with reference to the accompanying drawings, wherein

FIG. 1 is a schematic block diagram for describing a display device according to embodiments of the disclosure;

FIG. 2 is a schematic block diagram for describing a subpixel among subpixels included in the display device of FIG. 1;

FIG. 3 is a schematic plan view for describing a display panel of the display device of FIG. 1;

FIG. 4 is a schematic cross-sectional view for describing an embodiment of the display panel of FIG. 3;

FIG. 5 is a schematic cross-sectional view illustrating an embodiment of the display panel of FIG. 3;

FIGS. 6 to 9 are schematic views for describing a light-emitting element according to an embodiment of the disclosure;

FIGS. 10 to 22 are schematic views for describing a pixel of pixels included in the display panel of FIG. 3;

FIGS. 23 to 47 are schematic views for describing a method of manufacturing a display device including the pixel of FIGS. 10 to 22;

FIGS. 48 to 57 are schematic views for describing an embodiment in which residues of a photoresist pattern layer are generated;

FIG. 58 is a schematic block diagram for describing a display system according to an embodiment; and

FIGS. 59 to 62 are schematic perspective views for describing application examples of the display system of FIG. 58.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “coupled to,” or “connected to” another element or layer, it may be directly on, coupled to, or connected to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Although the terms “first,” “second,” etc. may be used herein to describe various elements, these elements should not be limited by these terms. These terms are used to distinguish one element from another element. Thus, a first element described below could be termed as a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

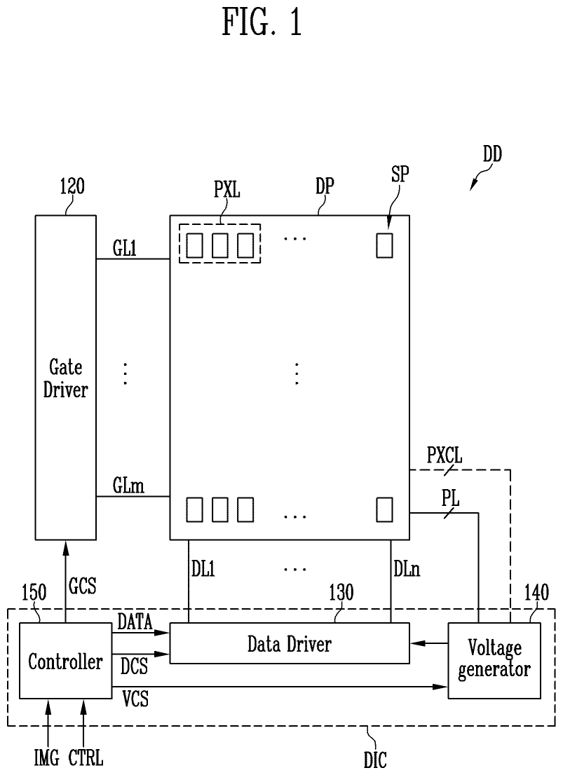

FIG. 1 is a schematic block diagram for describing a display device according to embodiments of the disclosure.

Referring to FIG. 1, a display device DD may include a display panel DP, a gate driver 120, a data driver 130, a voltage generator 140, and a controller 150.

The display panel DP may include subpixels SP. The subpixels SP may be electrically connected to the gate driver 120 through gate lines (e.g., first to m^{th} gate lines GL1 to GLm). The subpixels SP may be electrically connected to the data driver 130 through data lines (e.g., first to n^{th} data lines DL1 to DLn).

The subpixels SP may generate light with two or more colors. For example, each of the subpixels SP may generate light such as red, green, blue, cyan, magenta, or yellow light.

Two or more subpixels among the subpixels SP may form a pixel PXL. For example, the pixel PXL may include three subpixels as shown in FIG. 1. The pixel PXL may emit light with various colors and various luminances according to the combination of light (e.g., pieces of light) emitted from the subpixels included in the pixel PXL.

The gate driver 120 may be electrically connected to the subpixels SP disposed (e.g., arranged) in a row direction through the first to m^{th} gate lines GL1 to GLm. The gate driver 120 may output gate signals to the first to m^{th} gate lines GL1 to GLm in response to a gate control signal GCS. In embodiments, the gate control signal GCS may include a start signal indicating the start of each frame, a horizontal synchronization signal, or the like.

The gate driver 120 may be disposed at a side of the display panel DP. However, embodiments are not limited thereto. For example, the gate driver 120 may be divided into two or more physically and/or logically separated drivers, and these drivers may be disposed at a side of the display panel DP and another side surface opposite to the side. The gate driver 120 may be disposed adjacent to (e.g., disposed around) the display panel DP in various shapes according to embodiments.

The data driver 130 may be electrically connected to the subpixels SP disposed (e.g., arranged) in a column direction (e.g., a column direction of the display panel DP) through the first to n^{th} data lines DL1 to DLn. The data driver 130 may receive image data DATA and a data control signal DCS from the controller 150. The data driver 130 may operate the display panel DP in response to the data control signal DCS. In embodiments, the data control signal DCS may include a source start signal, a source shift clock, a source output enable signal, or the like.

The data driver 130 may receive voltages from voltage generator 140. The data driver 130 may apply data signals having grayscale voltages corresponding to the image data DATA to the first to n^{th} data lines DL1 to DLn using the received voltages. In case that a gate signal is applied to each of the first to m^{th} gate lines GL1 to GLm, data signals corresponding to the image data DATA may be applied to the data lines DL1 to DLn. Accordingly, the subpixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate other parts (e.g., the gate driver 120, the data driver 130, the controller 150, the display panel DP, or the like) in response to a voltage control signal VCS from the controller 150. The voltage generator 140 may generate voltages and provide the generated voltages to components of the display device DD, such as the gate driver 120, the data driver 130, the controller 150, the display panel DP, or the like. The voltage generator 140 may generate voltages by receiving an input voltage from the outside of the display device DD and regulating the received voltage. For example, the voltage generator 140 may receive and regulate the input voltage from the outside of the display device DD, and apply the generated voltages to the gate driver 120, the data driver 130, the controller 150, the display panel DP, or the like.

The voltage generator 140 may generate a first power voltage and a second power voltage. The generated first and second power voltages may be provided to the subpixels SP through power lines PL. In an embodiment, at least one of the first and second power voltages may be provided from the outside of the display device DD.

The voltage generator 140 may provide various voltages and/or signals. For example, the voltage generator 140 may provide one or more initialization voltages to be applied to the subpixels SP of the display panel DP. For example, during a sensing operation of sensing electrical characteristics of transistors and/or light-emitting elements of the subpixels SP, a voltage (e.g., a certain or selectable reference voltage) may be applied to the first to n^{th} data lines DL1 to DLn, and the voltage generator 140 may generate the reference voltage and transmit the generated reference voltage to the data driver 130. For example, during a display operation of displaying an image on the display panel DP, the voltage generator 140 may generate common pixel control signals, and the common pixel control signals may be applied to the subpixels SP. In embodiments, the voltage generator 140 may provide pixel control signals to the subpixels SP through pixel control lines PXCL. In FIG. 1, the pixel control lines PXCL are shown as being electrically connected between the voltage generator 140 and the display panel DP, but embodiments are not limited thereto. For example, the pixel control lines PXCL may be electrically connected between the gate driver 120 and the display panel DP. The pixel control signals may be transmitted from the voltage generator 140 to the pixel control lines PXCL through the gate driver 120.

The controller 150 may control the overall operation of the display device DD. The controller 150 may receive input image data IMG and a corresponding control signal CTRL from the outside. The controller 150 may provide the gate control signal GCS, the data control signal DCS, and the voltage control signal VCS in response to the received control signal CTRL.

The controller 150 may output the image data DATA by converting the input image data IMG to be suitable for the display device DD or the display panel DP. For example, the controller 150 may convert the image data DATA and output the converted image data DATA to parts of the display device DD (e.g., the data driver 130, the display panel DP, or the like). In embodiments, the controller 150 may output the image data DATA by aligning the input image data IMG to be suitable for the subpixels SP disposed in a row. For example, the controller 150 may generate the image data DATA in response to the input image data IMG, and the image data DATA may be applied to other parts of the display device DD (e.g., the subpixels SP of the display panel DP, the data driver 130, or the like).

Two or more components of the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be components functionally separated in a driver integrated circuit DIC. In other embodiments, at least one of the data driver 130, the voltage generator 140, and the controller 150 may be (e.g., be provided as) a separate component from the driver integrated circuit DIC.

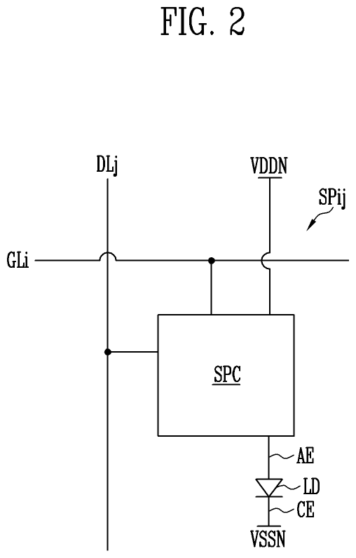

FIG. 2 is a schematic block diagram for describing a subpixel among the subpixels included in the display device of FIG. 1. In FIG. 2, among the subpixels SP of FIG. 1, a subpixel SPij disposed in an i^{th} row (i is an integer from 1 to m) and a j^{th} column (j is an integer from 1 to n) is shown as an example.

Referring to FIG. 2, the subpixel SPij may include a subpixel circuit SPC and a light-emitting element LD.

The light-emitting element LD may be electrically connected between a first power voltage node VDDN and a second power voltage node VSSN. The first power voltage node VDDN may be electrically connected to a power line of the power lines PL in FIG. 1 and receive a first power voltage. The second power voltage node VSSN may be electrically connected to another power line of the power lines PL in FIG. 1 and receive a second power voltage. The first power voltage may have a higher level than the second power voltage.

The light-emitting element LD may be electrically connected between an anode AE and a cathode CE. The anode AE may be electrically connected to the first power voltage node VDDN through the subpixel circuit SPC. For example, the anode AE may be electrically connected to the first power voltage node VDDN through one or more transistors included in the subpixel circuit SPC. The cathode CE may be electrically connected to the second power voltage node VSSN. The light-emitting element LD may emit light according to a current flowing from the anode AE to the cathode CE.

The subpixel circuit SPC may be electrically connected to an i^{th} gate line GLi among the first to m^{th} gate lines GL1 to GLm of FIG. 1 and a j^{th} data line DLj among the first to n^{th} data lines DL1 to DLn of FIG. 1. In response to a gate signal received through the i^{th} gate line GLi, the subpixel circuit SPC may control the light-emitting element LD and emit light according to a data signal received through the j^{th} data line DLj. In embodiments, the subpixel circuit SPC may be further electrically connected to the pixel control lines PXCL of FIG. 1. The subpixel circuit SPC may control the light-emitting element LD in further response to pixel control signals received through the pixel control lines PXCL.

The subpixel circuit SPC may include circuit elements such as transistors and one or more capacitors.

The transistors of the subpixel circuit SPC may include P-type transistors and/or N-type transistors. In embodiments, the transistors of the subpixel circuit SPC may include metal oxide semiconductor field effect transistors (MOSFETs). In embodiments, the transistors of the subpixel circuit SPC may include an amorphous silicon semiconductor, a monocrystalline silicon semiconductor, a polycrystalline silicon semiconductor, an oxide semiconductor, and the like. However, the disclosure is not limited thereto.

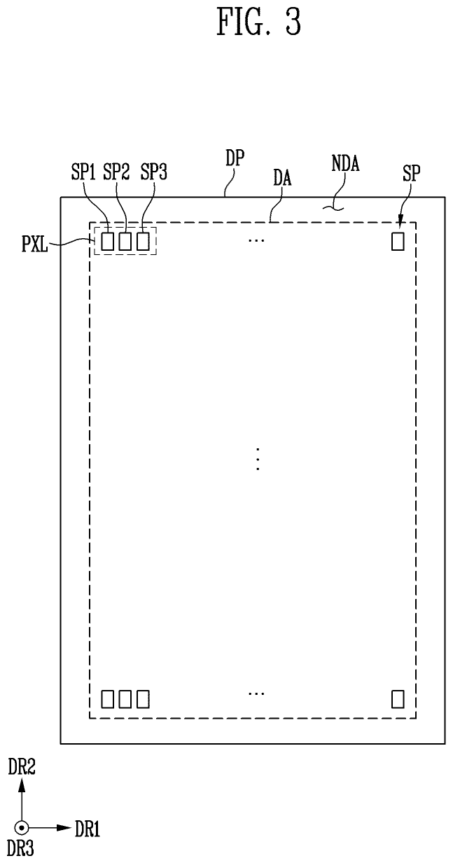

FIG. 3 is a schematic plan view for describing a display panel of the display device of FIG. 1.

Referring to FIG. 3, a display panel DP may include a display area DA and a non-display area NDA. The display panel DP may display an image through the display area DA. The non-display area NDA may be disposed adjacent to (e.g., disposed around) the display area DA.

The display panel DP may include subpixels SP disposed in the display area DA. The subpixels SP may be disposed (e.g., arranged) in a first direction DR1 and a second direction DR2 that intersects the first direction DR1. For example, the subpixels SP may be disposed (e.g., arranged) in a matrix form in the first direction DR1 and the second direction DR2. In other embodiments, the subpixels SP may be disposed (e.g., arranged) in a zigzag form in the first direction DR1 and the second direction DR2. The arrangement of the subpixels SP may vary according to embodiments. The first direction DR1 may be a row direction (e.g., a row direction of the display panel DP), and the second direction DR2 may be a column direction (e.g., a column direction of the display panel DP).

Two or more subpixels among the subpixels SP may form a pixel PXL. In FIG. 3, the pixel PXL may include three subpixels SP1, SP2, and SP3, but embodiments are not limited thereto. For example, the pixel PXL may include two subpixels. Hereinafter, for convenience of description, the pixel PXL may include first to third subpixels SP1, SP2, and SP3.

Each of the first to third subpixels SP1, SP2, and SP3 may generate light with one of various colors such as red, green, blue, cyan, magenta, and yellow. Hereinafter, for convenience of description, the first subpixel SP1 may generate red color light, the second subpixel SP2 may generate green color light, and the third subpixel SP3 may generate blue color light.

Each of the first to third subpixels SP1, SP2, and SP3 may include one or more light-emitting elements generating (or emitting) light. In some embodiments, the light-emitting elements of the first to third subpixels SP1, SP2, and SP3 may generate light of the same color. For example, the light-emitting elements of the first to third subpixels SP1, SP2, and SP3 may generate blue light. In other embodiments, the light-emitting elements of the first to third subpixels SP1, SP2, and SP3 may generate light (e.g., pieces of light) with different colors. For example, the light-emitting elements of the first to third subpixels SP1, SP2, and SP3 may generate light (e.g., pieces of light) with a red color, a green color, and a blue color, respectively.

The display panel DP may include light emitting elements emitting light independently of a separate light source. For example, the display panel DP may include a light-emitting diode (LED) display panel (LED display panel) using a microscale or nanoscale light-emitting diode as a light-emitting element or an organic light-emitting diode (OLED) display panel (OLED display panel) using an OLED as a light-emitting element.

Components for controlling the subpixels SP may be disposed in the non-display area NDA. Interconnects electrically connected to the subpixels SP, for example, the first to m^{th} gate lines GL1 to GLm, the first to n^{th} data lines DL1 to DLn, the power lines PL and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may form (or be implemented as) the driver integrated circuit DIC of FIG. 1 which is separate from the display panel DP, and the driver integrated circuit DIC may be electrically connected to interconnects disposed in the non-display area NDA. In other embodiments, the gate driver 120, the data driver 130, the voltage generator 140, and the controller 150 may form (or be implemented as) an integrated circuit separate from the display panel DP.

In embodiments, the display area DA may have various shapes. The display area DA may have a closed loop shape including straight and/or curved sides. For example, the display area DA may have shapes such as polygonal, circular, semicircular, and elliptical shapes. However, the disclosure is not limited thereto.

In embodiments, the display panel DP may have a flat display surface. In other embodiments, the display panel DP may have a display surface that is at least partially round. In embodiments, the display panel DP may be bendable, foldable, or rollable. The display panel DP and/or a substrate of the display panel DP may include materials having flexible properties.

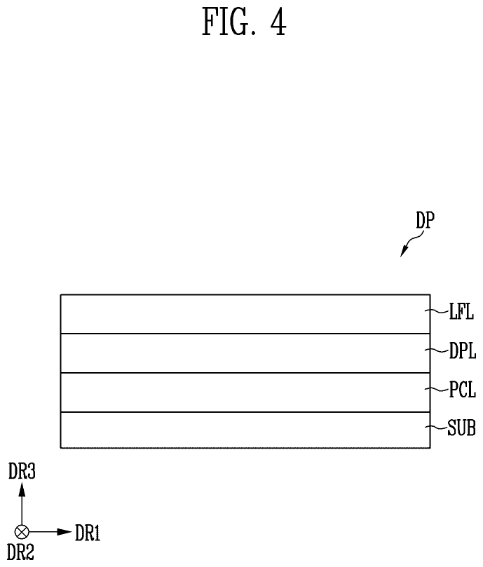

FIG. 4 is a schematic cross-sectional view for describing an embodiment of the display panel of FIG. 3.

Referring to FIG. 4, a display panel DP may include a substrate SUB, a pixel circuit layer PCL, a display element layer DPL, and a light functional layer LFL which are sequentially stacked on the substrate SUB in a third direction DR3 that intersects first and second directions DR1 and DR2.

The substrate SUB may include (e.g., be made of) an insulating material such as glass or a resin. For example, the substrate SUB may include a glass substrate. In other embodiments, the substrate SUB may include a polyimide (PI) substrate. In other embodiments, the substrate SUB may include a silicon wafer substrate formed using a semiconductor process.

In embodiments, the substrate SUB may include (e.g., be made of) a flexible material that is bendable or foldable and may have a single-layer structure or a multi-layer structure. For example, the flexible material of the substrate SUB may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, semiconductor patterns, and conductive patterns. The semiconductor patterns and the conductive patterns may be disposed between the insulating layers. The conductive patterns of the pixel circuit layer PCL may form (or function as) circuit elements, interconnects, and the like.

The circuit elements of the pixel circuit layer PCL may form a subpixel circuit SPC of each of the subpixels SP of FIG. 3. The circuit elements of the pixel circuit layer PCL may form (or be provided as) transistors and one or more capacitors of the subpixel circuit SPC.

Interconnects of the pixel circuit layer PCL may include interconnects electrically connected to the subpixels SP. The interconnects of the pixel circuit layer PCL may include various signal lines and/or voltage lines which are desirable to drive the display element layer DPL.

The display element layer DPL may be disposed on the pixel circuit layer PCL. The display element layer DPL may include light-emitting elements of the subpixels SP.

A light functional layer LFL may be disposed on the display element layer DPL. The light functional layer LFL may include light conversion patterns having color conversion particles and/or scattering particles. For example, the color conversion particles may include quantum dots. The quantum dots may change a wavelength (or a color) of light emitted from the display element layer DPL. The light functional layer LFL may further include light scattering patterns having scattering particles. In other embodiments, the light conversion patterns and the light scattering patterns may be omitted.

The light functional layer LFL may further include a color filter layer including color filters. Each of the color filters may selectively transmit light with a wavelength (e.g., a specific of selectable wavelength) or a color (e.g., a specific or selectable color). In other embodiments, the color filter layer may be omitted.

A window may be disposed (or provided) on the light functional layer LFL and protect an exposed surface (or an upper surface) of the display panel DP. The window may protect the display panel DP from an external impact. The window may be coupled to the light functional layer LFL through an optically transparent adhesive (or glue) member. The window may have a multilayer structure selected from a glass substrate, a plastic film, and a plastic substrate. The multilayer structure may be formed through a continuous process or an adhesion process using an adhesive layer. An entire portion of the window may be flexible.

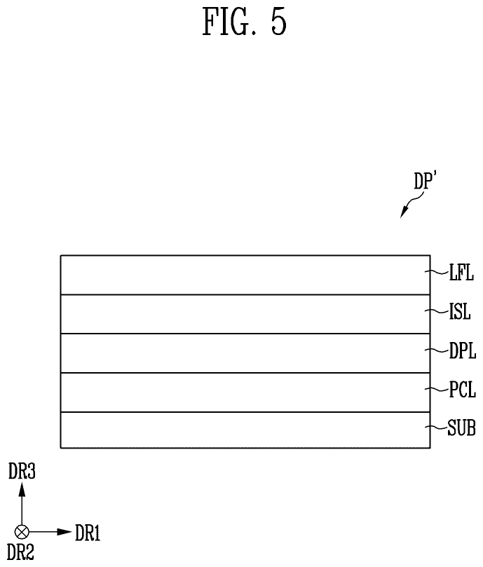

FIG. 5 is a schematic cross-sectional view illustrating an embodiment of the display panel of FIG. 3.

Referring to FIG. 5, a display panel DP′ may include a substrate SUB, a pixel circuit layer PCL, a display element layer DPL, an input sensing layer ISL, and a light functional layer LFL. In FIG. 5, the display panel DP′ is different from the display panel of FIG. 4 at least in the input sensing layer ISL. Hereinafter, detailed description of the same or similar constituent elements is omitted.

The input sensing layer ISL may detect a user input on an upper surface (or a display surface) of the display panel DP′. The input sensing layer ISL may include components suitable for detecting external objects such as a user's hand and a pen. For example, the input sensing layer ISL may include touch electrodes.

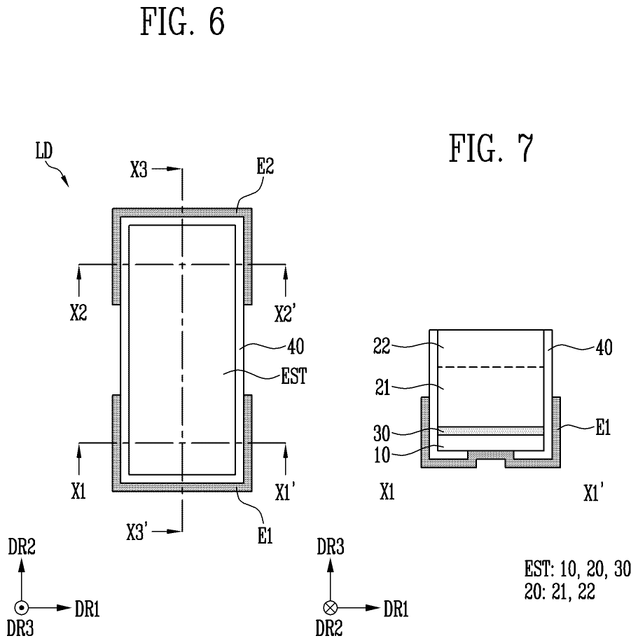

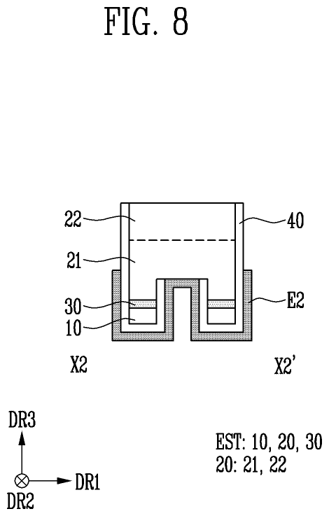

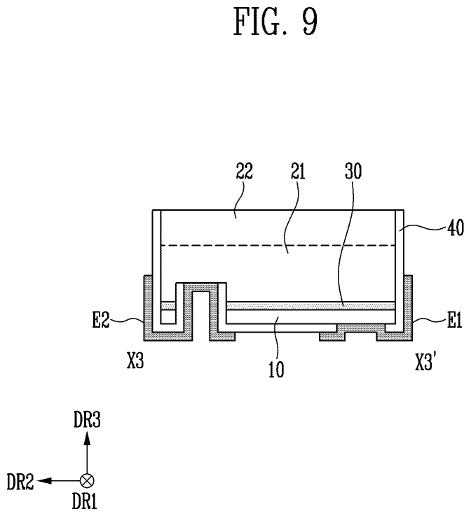

FIGS. 6 to 9 are schematic views for describing a light-emitting element according to an embodiment of the disclosure. FIG. 6 is a schematic plan view for describing the light-emitting element according to an embodiment of the disclosure. FIG. 7 is a schematic cross-sectional view taken along line X1-X1′ of FIG. 6. FIG. 8 is a schematic cross-sectional view taken along line X2-X2′ of FIG. 6. FIG. 9 is a schematic cross-sectional view taken along line X3-X3′ of FIG. 6.

Referring to FIGS. 6 to 9, a light-emitting element LD is shown. The light-emitting element LD may be (e.g., be provided as) a light-emitting element LD (e.g., refer to FIG. 2) for each of the subpixels SP of FIG. 3.

The light-emitting element LD may include an emission stack EST, an insulating film 40, an anode connection electrode E1, and a cathode connection electrode E2. The emission stack EST may include a first semiconductor layer 10, an active layer 30, and a second semiconductor layer 20 sequentially stacked in a third direction DR3.

The first semiconductor layer 10 may provide holes. The first semiconductor layer 10 may have first polarity. For example, the first semiconductor layer 10 may include at least one p-type semiconductor layer. For example, the first semiconductor layer 10 may include at least one semiconductor material selected from gallium nitride (GaN), aluminum gallium nitride (AlGaN), indium gallium nitride (InGaN), aluminum nitride (AlN), and indium nitride (InN) and may be a p-type semiconductor layer doped with a first conductive dopant (or a p-type dopant) such as magnesium (Mg), zinc (Zn), calcium (Ca), strontium (Sr), or barium (Ba). However, a material forming (or included in) the first semiconductor layer 10 is not limited thereto, and various other materials may form (or be included in) the first semiconductor layer 10. In an embodiment of the disclosure, the first semiconductor layer 10 may include a gallium nitride (GaN) semiconductor material doped with the first conductive dopant (or the p-type dopant).

The second semiconductor layer 20 may be disposed on the first semiconductor layer 10 and may provide electrons. The second semiconductor layer 20 may have second polarity that is different from the first polarity. For example, the second semiconductor layer 20 may include at least one n-type semiconductor layer. For example, the second semiconductor layer 20 may include at least one semiconductor material selected from gallium nitride (GaN), aluminum gallium nitride (AlGaN), indium gallium nitride (InGaN), aluminum nitride (AlN), and indium nitride (InN) and may be an n-type semiconductor layer doped with a second conductive dopant (or an n-type dopant) such as silicon (Si), germanium (Ge), or tin (Sn). However, a material forming (or included in) the second semiconductor layer 20 is not limited thereto, and various other materials may form (or be included in) the second semiconductor layer 20. In an embodiment of the disclosure, the second semiconductor layer 20 may include a gallium nitride (GaN) semiconductor material doped with the second conductive dopant (or the n-type dopant).

In an embodiment, the second semiconductor layer 20 may include a first doped portion 21 and a second doped portion 22 sequentially stacked in the third direction DR3. The first doped portion 21 may be a portion doped with a relatively high concentration of a dopant, and the second doped portion 22 may be doped with a relatively low concentration of a dopant or may be a portion that is not substantially doped with a dopant. For example, a first average doping concentration of a dopant in the first doped portion 21 may be higher than a second average doping concentration of a dopant in the second doped portion 22.

The active layer 30 may be disposed (e.g., interposed) between the first semiconductor layer 10 and the second semiconductor layer 20 and may provide an area in which electrons and holes recombine. In case that electrons and holes recombine in the active layer 30, an energy level may be changed (e.g., may transition) to a lower energy level, and light having a wavelength corresponding to the transition of the energy level may be generated. The active layer 30 may be formed as a single- or multi-quantum well structure. In case that the active layer 30 is formed in a multi-quantum well structure, parts (or layers) including a barrier layer, a strain reinforcing layer, and a well layer may be repeatedly stacked each other and form the active layer 30. However, the active layer 30 is not limited to the above-described structure.

The insulating film 40 may cover at least a portion of an outer peripheral surface of the emission stack EST. For example, the insulating film 40 may expose an upper surface of the emission stack EST. The insulating film 40 may prevent an electrical short circuit that may occur in case that the active layer 30 comes into contact with a conductive material other than the first and second semiconductor layers 10 and 20. For example, the active layer 30 may be electrically connected to the first and second semiconductor layers 10 and 20, and the insulating film 40 may electrically insulate a remaining portion of the active layer 30 from other parts. In an embodiment, the insulating film 40 may include a transparent insulating material.

The anode connection electrode E1 may be electrically connected to the first semiconductor layer 10. For example, the anode connection electrode E1 may be in direct contact with an exposed lower surface of the first semiconductor layer 10 without being covered by the insulating film 40. The anode connection electrode E1 may be adjacent (e.g., surround) at least a portion of the outer peripheral surface of the emission stack EST. For example, as shown in FIGS. 7 and 9, the anode connection electrode E1 may extend from a lower surface of the emission stack EST and be adjacent to (e.g., surround) a portion of a side surface of the emission stack EST.

In an embodiment, the anode connection electrode E1 may include (e.g., be made of) a conductive material having a reflectance (e.g., a certain or selectable reflectance). The emission efficiency of light emitted from the light-emitting element LD may be improved. For example, the anode connection electrode E1 may include at least one metal of silver (Ag), magnesium (Mg), aluminum (Al), platinum (Pt), palladium (Pd), gold (Au), nickel (Ni), neodymium (Nd), iridium (Ir), chromium (Cr), and titanium (Ti). For example, the anode connection electrode E1 may include an alloy of the above-described metals. However, the material of the anode connection electrode E1 is not limited thereto.

The cathode connection electrode E2 may be electrically connected to the second semiconductor layer 20. For example, the cathode connection electrode E2 may be in direct contact with a portion of the first doped portion 21 exposed by a mesa-hole formed in the third direction DR3 from the lower surface of the emission stack EST. In the mesa-hole, the insulating film 40 may be disposed (e.g., interposed) between the cathode connection electrode E2 and the active layer 30 and between the cathode connection electrode E2 and the first semiconductor layer 10.

The cathode connection electrode E2 may be adjacent to (e.g., surround) at least a portion of the outer peripheral surface of the emission stack EST. For example, as shown in FIGS. 8 and 9, the cathode connection electrode E2 may extend from the lower surface of the emission stack EST and be adjacent to (e.g., surround) a portion of the side surface of the emission stack EST. The cathode connection electrode E2 may be spaced apart from the anode connection electrode E1.

In an embodiment, the cathode connection electrode E2 may include (e.g., be made of) a conductive material having a reflectance (e.g., a certain or selectable reflectance). The emission efficiency of light emitted from the light-emitting element LD may be improved. For example, the cathode connection electrode E2 may include at least one metal of silver (Ag), magnesium (Mg), aluminum (Al), platinum (Pt), palladium (Pd), gold (Au), nickel (Ni), neodymium (Nd), iridium (Ir), chromium (Cr), and titanium (Ti). For example, the cathode connection electrode E2 may include an alloy of the above-described metals. However, the material of the cathode connection electrode E2 is not limited thereto.

In an embodiment, the light-emitting element LD may be an ultra-small LED (micro-LED) and may be referred to as a flip chip type light-emitting element.

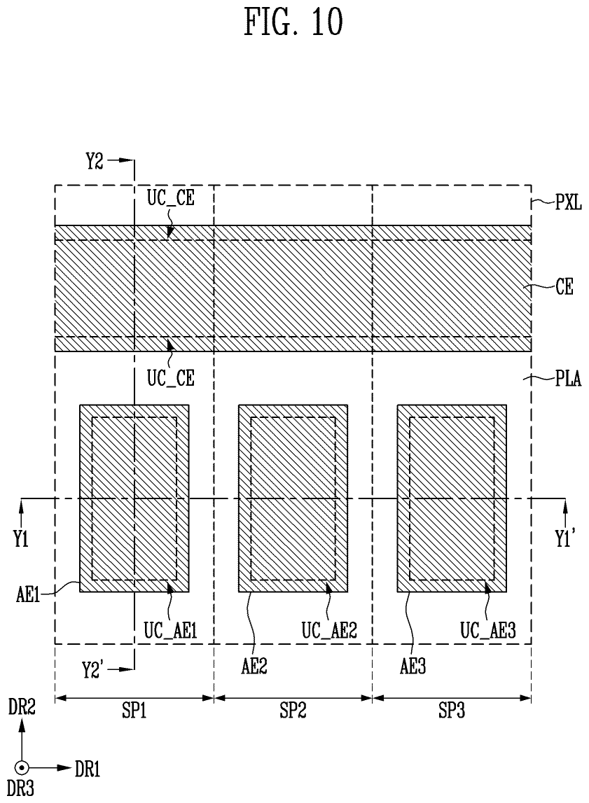

Hereinafter, with reference to FIGS. 10 to 22, detailed description of a pixel PXL including the light-emitting element LD described with reference to FIGS. 6 to 9 is provided below.

FIGS. 10 to 22 are schematic views for describing a pixel of the pixels included in the display panel of FIG. 3.

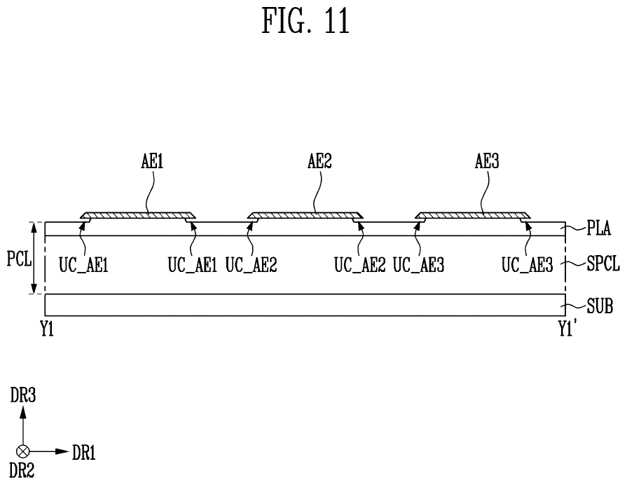

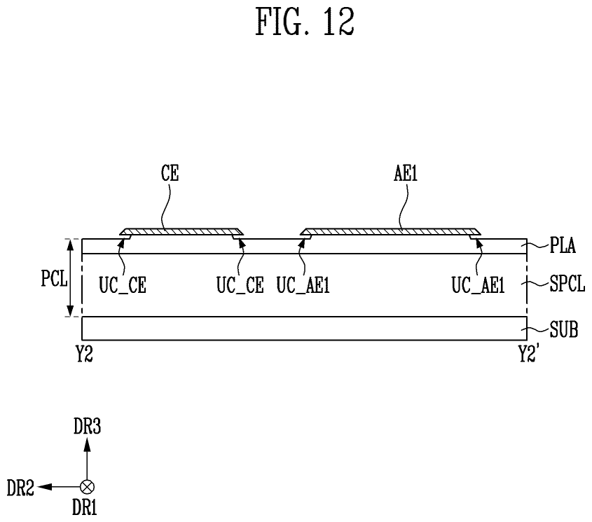

FIG. 10 is a schematic plan view illustrating some components included in the pixel. In FIG. 10, detailed description of the same or similar constituent elements in the pixel is omitted for convenience of description. FIG. 11 is a schematic cross-sectional view taken along line Y1-Y1′ of FIG. 10. FIG. 12 is a schematic cross-sectional view taken along line Y2-Y2′ of FIG. 10.

Referring to FIG. 10, a pixel PXL may include a first subpixel SP1, a second subpixel SP2, and a third subpixel SP3. The first to third subpixels SP1, SP2, and SP3 may be disposed (e.g., arranged) in the first direction DR1. However, the arrangement of the first to third subpixels SP1, SP2, and SP3 is not limited thereto and may be changed in various ways according to embodiments. For example, the first to third subpixels SP1, SP2, and SP3 may be disposed (e.g., arranged) in a zigzag form.

The first to third subpixels SP1, SP2, and SP3 may include a first anode AE1, a second anode AE2, a third anode AE3, and a cathode CE.

The first anode AE1 may be (e.g., be provided as) an anode AE (e.g., refer to FIG. 2) electrically connected to a subpixel circuit SPC (e.g., refer to FIG. 2) of the first subpixel SP1. The first anode AE1 may be disposed on a planarization layer PLA.

The second anode AE2 may be (e.g., be provided as) an anode AE (e.g., refer to FIG. 2) electrically connected to a subpixel circuit SPC (e.g., refer to FIG. 2) of the second subpixel SP2. The second anode AE2 may be disposed on the planarization layer PLA. The second anode AE2 may be spaced apart from the first anode AE1 in a first direction DR1.

The third anode AE3 may be (e.g., be provided as) an anode AE (e.g., refer to FIG. 3) electrically connected to a subpixel circuit SPC (e.g., refer to FIG. 2) of the third subpixel SP3. The third anode AE3 may be disposed on the planarization layer PLA. The third anode AE3 may be spaced apart from the second anode AE2 in the first direction DR1.

The cathode CE may be spaced apart from the first to third anodes AE1, AE2, and AE3 in a second direction DR2. The cathode CE may be disposed on the planarization layer PLA. The cathode CE may extend in the first direction DR1. The cathode CE may be (e.g., be used as) a common electrode for the pixel PXL and other pixels adjacent to the pixel PXL. Although not shown, the cathode CE may extend not only in the first direction DR1 but also in the second direction DR2 and may be (e.g., be used as) a common electrode for all of the subpixels SP of FIG. 3.

Referring to FIGS. 10 to 12, the pixel PXL may include a substrate SUB, a pixel circuit layer PCL, the first to third anodes AE1, AE2, and AE3, and the cathode CE.

The pixel circuit layer PCL may be disposed on the substrate SUB. The pixel circuit layer PCL may include a pixel circuit base layer (or a pixel circuit forming layer) SPCL and the planarization layer PLA disposed on the pixel circuit base layer SPCL.

The pixel circuit base layer SPCL may include insulating layers, semiconductor patterns, and conductive patterns which are stacked each other on the substrate SUB. The semiconductor patterns and the conductive patterns may be positioned between the insulating layers. The conductive patterns may include at least one material selected from copper (Cu), molybdenum (Mo), tungsten (W), aluminum neodymium (AlNd), titanium (Ti), aluminum (Al), and silver (Ag). However, the disclosure is not limited thereto. The conductive patterns may include an alloy including the above-described metals.

The semiconductor patterns and the conductive patterns of the pixel circuit base layer SPCL may form (e.g., function as) transistors and capacitors of first to third subpixel circuits of the first to third subpixels SP1, SP2, and SP3. The conductive patterns of the pixel circuit base layer SPCL may further form (e.g., function as) interconnects, for example, the first to m^{th} gate lines GL1 to GLm, the first to n^{th} data lines DL1 to DLn, the power lines PL, and the pixel control lines PXCL of FIG. 1.

For example, the pixel circuit base layer SPCL may include the first to third subpixel circuits of the first to third subpixels SP1, SP2, and SP3. The first anode AE1 may be electrically connected to the first subpixel circuit through a through-hole passing through one or more insulating layers of various insulating layers forming (or included in) the pixel circuit layer PCL. The second anode AE2 may be electrically connected to the second subpixel circuit through a through-hole passing through one or more insulating layers of the various insulating layers forming (or included in) the pixel circuit layer PCL. The third anode AE3 may be electrically connected to the third subpixel circuit through a through-hole passing through one or more insulating layers of the various insulating layers forming (or included in) the pixel circuit layer PCL.

The planarization layer PLA may be a layer that forms an uppermost layer of the pixel circuit layer PCL. The planarization layer PLA may include an inorganic insulating layer including an inorganic material and/or an organic insulating layer including an organic material. The inorganic insulating layer may include, for example, at least one selected from metal oxides such as silicon oxide, silicon nitride, silicon oxynitride, and aluminum oxide. The organic insulating layer may include, for example, at least one selected from an acrylic resin, an epoxy resin, a phenol resin, a polyamide resin, a polyimide resin, an unsaturated polyester resin, a poly-phenylene sulfide resin, and a benzocyclobutene resin. However, the disclosure is not limited thereto.

In an embodiment, at least some of various interconnects of a display panel DP and/or a display device DD may be further disposed between the pixel circuit base layer SPCL and the planarization layer PLA.

In an embodiment, the planarization layer PLA may include a first anode undercut UC_AE1, a second anode undercut UC_AE2, a third anode undercut UC_AE3, and a cathode undercut UC_CE.

The first anode undercut UC_AE1 may be formed along an edge of the first anode AE1 in a plan view between the planarization layer PLA and a lower surface of the first anode AE1.

The second anode undercut UC_AE2 may be formed along an edge of the second anode AE2 in a plan view between the planarization layer PLA and a lower surface of the second anode AE2.

The third anode undercut UC_AE3 may be formed along an edge of the third anode AE3 in a plan view between the planarization layer PLA and a lower surface of the third anode AE3.

The cathode undercut UC_CE may be formed along an edge of the cathode CE in a plan view between the planarization layer PLA and a lower surface of the cathode CE.

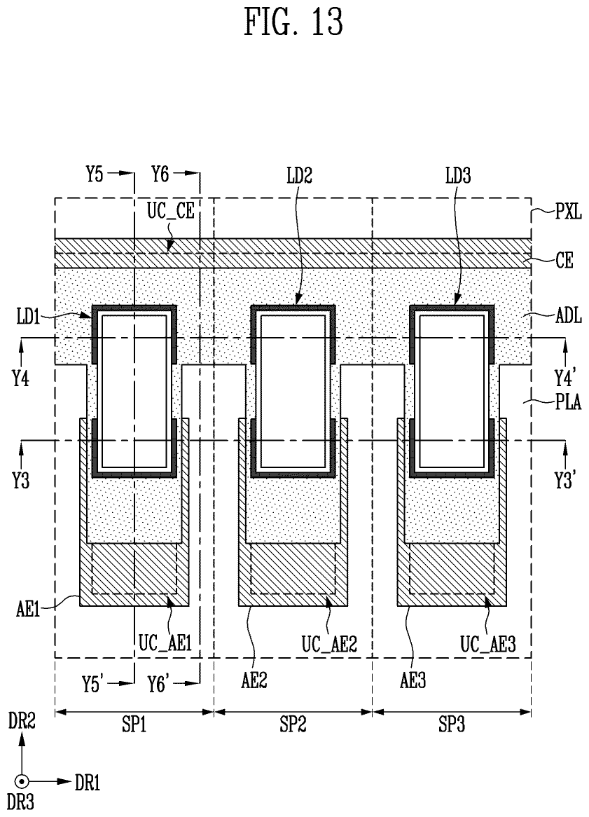

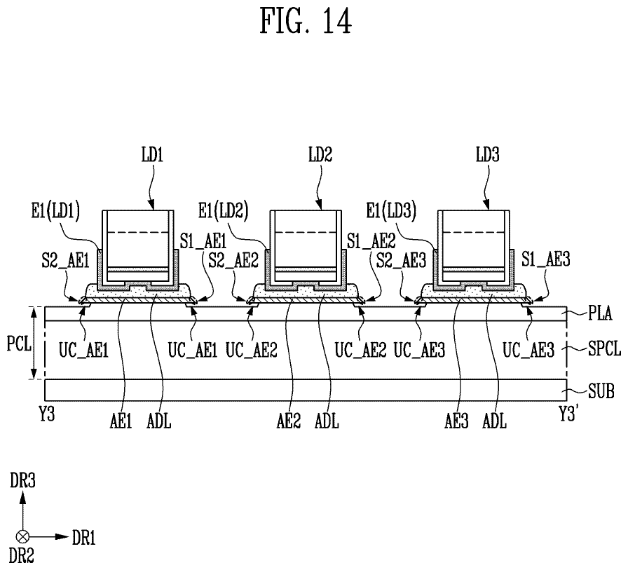

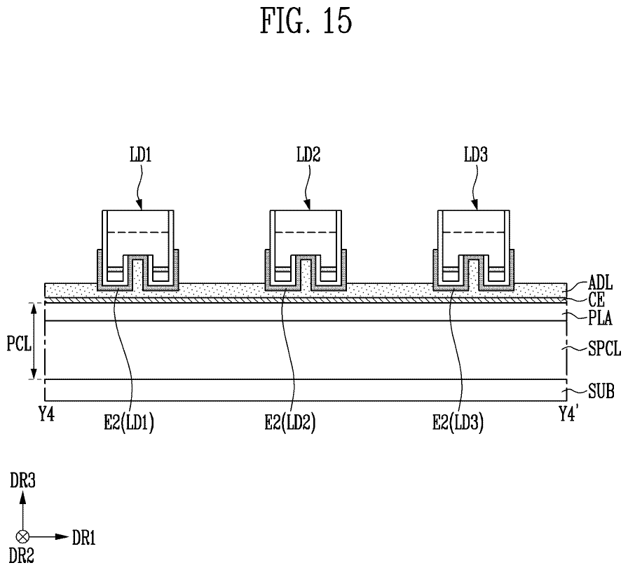

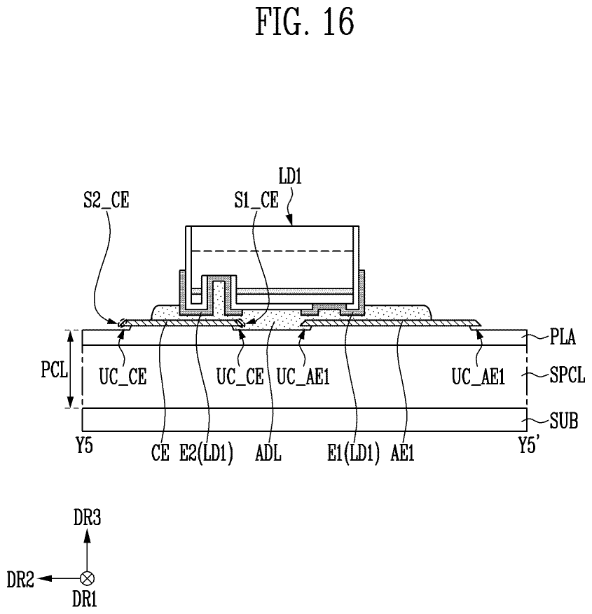

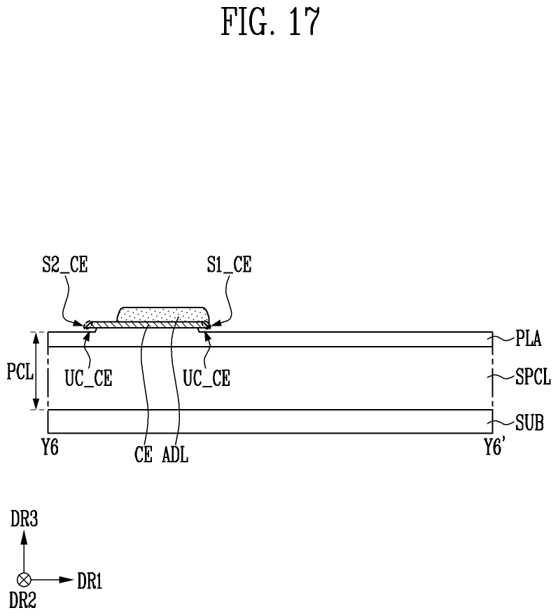

FIG. 13 is a schematic plan view further illustrating some other components included in a pixel in addition to the components described with reference to FIG. 10. In FIG. 13, detained description of the same or similar constituent elements in the pixel is omitted for convenience of description. FIG. 14 is a schematic cross-sectional view taken along the Y3-Y3′ line of FIG. 13. FIG. 15 is a schematic cross-sectional view taken along line Y4-Y4′ of FIG. 13. FIG. 16 is a schematic cross-sectional view taken along line Y5-Y5′ of FIG. 13. FIG. 17 is a schematic cross-sectional view taken along line Y6-Y6′ of FIG. 13.

Referring to FIG. 13, a pixel PXL may include an adhesive layer ADL, a first light-emitting element LD1, a second light-emitting element LD2, and a third light-emitting element LD3.

The adhesive layer ADL may be disposed on a portion of a first anode AE1, a portion of a second anode AE2, a portion of a third anode AE3, and a portion of a cathode CE. For example, the adhesive layer ADL may include an extension portion that extends in a first direction DR1 on the cathode CE, a first protrusion that protrudes from the extension portion in a direction opposite to a second direction DR2 and extends above the first anode AE1, a second protrusion that protrudes from the extension portion in the direction opposite to the second direction DR2 and extends above the second anode AE2, and a third protrusion that protrudes from the extension portion in the direction opposite to the second direction DR2 and extends above the third anode AE3. For example, the first to third protrusions of the adhesive layer ADL may be disposed on a portion of the first anode AE1, a portion of the second anode AE2, and a portion of the third anode AE3, respectively. The adhesive layer ADL may include an adhesive (or sticky) insulating material.

Each of the first to third light-emitting elements LD1, LD2, and LD3 may be substantially the same as (or similar to) the light-emitting element LD described with reference to FIGS. 6 to 9. The first to third light-emitting elements LD1, LD2, and LD3 may be disposed on the adhesive layer ADL. The first to third light-emitting elements LD1, LD2, and LD3 may be fixed at positions (e.g., preset or selectable positions) by the adhesive layer ADL.

The first light-emitting element LD1 may be (e.g., be provided as) a light-emitting element LD (e.g., refer to FIG. 2) of a first subpixel SP1. A portion of the first light-emitting element LD1 may overlap the first anode AE1 in a plan view, and another portion of the first light-emitting element LD1 may overlap the cathode CE in a plan view.

The second light-emitting element LD2 may be (e.g., be provided as) a light-emitting element LD (e.g., refer to FIG. 2) of a second subpixel SP2. A portion of the second light-emitting element LD2 may overlap the second anode AE2 in a plan view, and another portion of the second light-emitting element LD2 may overlap the cathode CE in a plan view.

The third light-emitting element LD3 may be (e.g., be provided as) a light-emitting element LD (e.g., refer to FIG. 2) of a third subpixel SP3. A portion of the third light-emitting element LD3 may overlap the third anode AE3 in a plan view, and another portion of the third light-emitting element LD3 may overlap the cathode CE in a plan view.

Referring to FIGS. 13 to 17, each of the first to third light-emitting elements LD1, LD2, and LD3 may be disposed in (e.g., partially buried in) the adhesive layer ADL. The first to third light-emitting elements LD1, LD2, and LD3 may be spaced apart from the first to third anodes AE1, AE2, and AE3 and the cathode CE in a third direction DR3 by the adhesive layer ADL.

Referring to FIGS. 13 and 14, the adhesive layer ADL may be disposed (e.g., interposed) between the first anode AE1 and an anode connection electrode E1 (LD1) of the first light-emitting element LD1 (hereinafter referred to as a first anode connection electrode), between the second anode AE2 and an anode connection electrode E1 (LD2) of the second light-emitting element LD2 (hereinafter referred to as a second anode connection electrode), and between the third anode AE3 and an anode connection electrode E1 (LD3) of the third light-emitting element LD3 (hereinafter referred to as a third anode connection electrode). For example, the adhesive layer ADL may expose side surfaces of the first to third anodes AE1, AE2, and AE3.

The adhesive layer ADL may expose a first side surface S1_AE1 facing the second anode AE2 among side surfaces of the first anode AE1 and a second side surface S2_AE2 opposite to the first side surface S1_AE1. For example, the adhesive layer ADL may expose the first and second side surfaces S1_AE1 and S2_AE1 of the first anode AE1.

The adhesive layer ADL may expose the second side surface S2_AE2 facing the first anode AE1 among side surfaces of the second anode AE2 and a first side surface S1_AE2 opposite to the second side surface S2_AE2. For example, the adhesive layer ADL may expose the first and second side surfaces S1_AE2 and S2_AE2 of the second anode AE2.

The adhesive layer ADL may expose a second side surface S2_AE3 facing the second anode AE2 among side surfaces of the third anode AE3 and a first side surface S1_AE3 opposite to the second side surface S2_AE3. For example, the adhesive layer ADL may expose the first and second side surfaces S1_AE3 and S2_AE3 of the third anode AE3.

Referring to FIGS. 13 and 15, the adhesive layer ADL may be disposed (e.g., interposed) between the cathode CE and a cathode connection electrode E2 (LD1) of the first light-emitting element LD1 (hereinafter, a first cathode connection electrode), between the cathode CE and a cathode connection electrode E2 (LD2) of the second light-emitting element LD2 (hereinafter referred to as a second cathode connection electrode), and between the cathode CE and a cathode connection electrode E2 (LD3) of the third light-emitting element LD3 (hereinafter referred to as a third cathode connection electrode).

Referring to FIGS. 13 and 16, in an area in which the first light-emitting element LD1 is disposed, the adhesive layer ADL may be disposed between the first anode AE1 and the cathode CE. The adhesive layer ADL may fill a first anode undercut UC_AE1 and a cathode undercut UC_CE between the first anode AE1 and the cathode CE.

The adhesive layer ADL may cover (e.g., completely cover) a first side surface S1_CE facing the first anode AE1 among side surfaces of the cathode CE and expose a second side surface S2_CE opposite to the first side surface S1_CE. For example, the adhesive layer ADL may cover the first and second side surfaces S1_CE and S2_CE of the cathode CE.

The adhesive layer ADL may cover an upper surface of the cathode CE adjacent to the first side surface S1_CE of the cathode CE and expose an upper surface of the cathode CE adjacent to the second side surface S2_CE of the cathode CE.

Cross-sectional shapes of areas, in which the second and third light-emitting elements LD2 and LD3 are disposed, not shown, may be substantially the same as (similar to) a cross-sectional shape of the area, in which the first light-emitting element LD1 is disposed, shown in FIG. 16. Thus, detailed description of the same or similar constituent elements is omitted.

Referring to FIGS. 13 and 17, a cross-sectional shape of an area in which the first to third light-emitting elements LD1, LD2, and LD3 are not disposed is shown.

The adhesive layer ADL may cover (e.g., completely cover) the first side surface S1_CE of the cathode CE and expose the second side surface S2_CE of the cathode CE. The adhesive layer ADL may cover an upper surface of the cathode CE adjacent to the first side surface S1_CE of the cathode CE and expose an upper surface of the cathode CE adjacent to the second side surface S2_CE of the cathode CE. For example, the adhesive layer ADL may only cover a portion of the cathode CE adjacent to the first side surface S1_CE of the cathode CE. In the area shown in FIG. 17 (and areas adjacent thereto), the adhesive layer ADL may not fill the cathode undercut UC_CE adjacent to the first side surface S1_CE of the cathode CE.

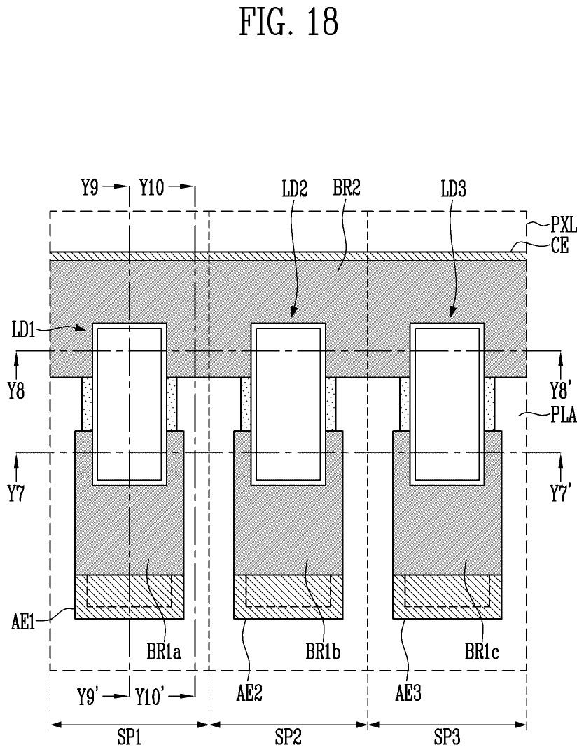

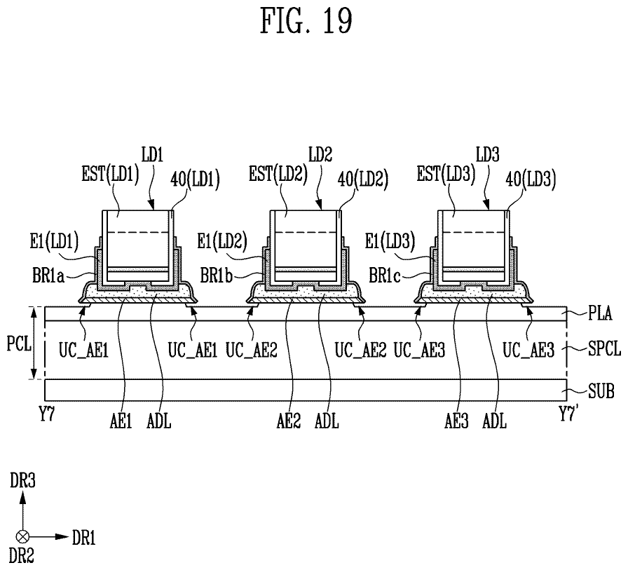

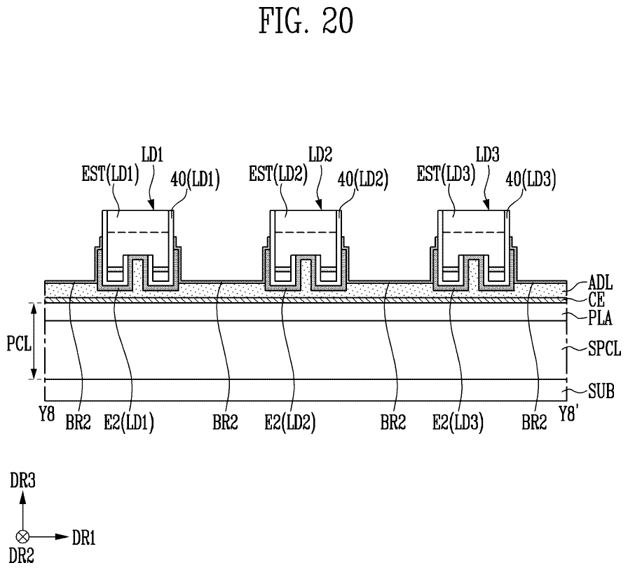

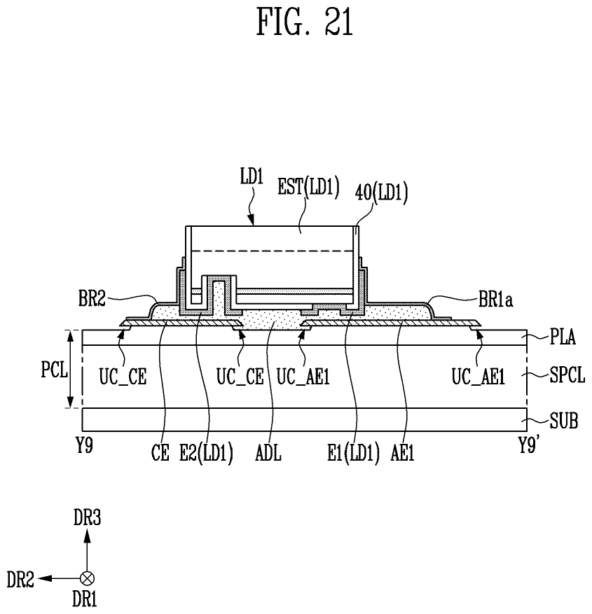

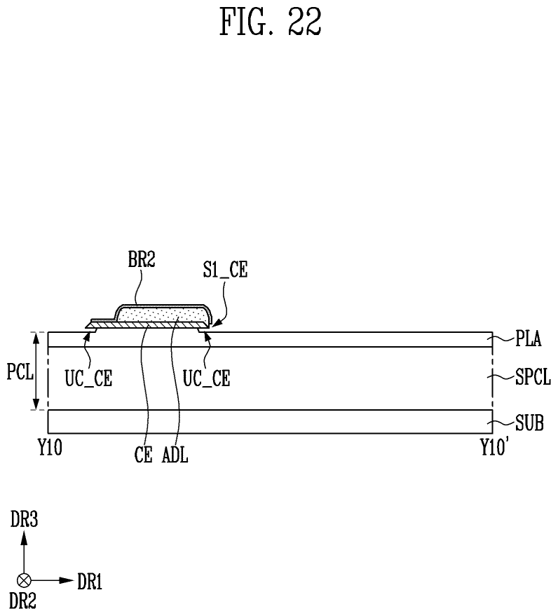

FIG. 18 is a schematic plan view further illustrating some other components included in a pixel in addition to the components described with reference to FIG. 13. FIG. 19 is a schematic cross-sectional view taken along line Y7-Y7′ of FIG. 18. FIG. 20 is a schematic cross-sectional view taken along line Y8-Y8′ of FIG. 18. FIG. 21 is a schematic cross-sectional view taken along line Y9-Y9′ of FIG. 18. FIG. 22 is a schematic cross-sectional view taken along line Y10-Y10′ of FIG. 18.

Referring to FIG. 18, a pixel PXL may include a first anode bridge electrode BR1a, a second anode bride electrode BR1b, a third anode bridge electrode BR1c, and a cathode bridge electrode BR2.

The first anode bridge electrode BR1a may electrically connect a first anode AE1 and a first anode connection electrode E1 (LD1). The first anode bridge electrode BR1a may be in direct contact with the first anode AE1 and the first anode connection electrode E1 (LD1).

The second anode bridge electrode BR1b may electrically connect a second anode AE2 and a second anode connection electrode E1 (LD2). The second anode bridge electrode BR1b may be in direct contact with the second anode AE2 and the second anode connection electrode E1 (LD2).

The third anode bridge electrode BRIc may electrically connect a third anode AE3 and a third anode connection electrode E1 (LD3). The third anode bridge electrode BRIc may be in direct contact with the third anode AE3 and the third anode connection electrode E1 (LD3).

The cathode bridge electrode BR2 may electrically connect a cathode CE and first to third cathode connection electrodes E2 (LD1), E2 (LD2), and E2 (LD3). The cathode bridge electrode BR2 may be in direct contact with the cathode CE and the first to third cathode connection electrodes E2 (LD1), E2 (LD2), and E2 (LD3).

The first to third anode bridge electrodes BR1a, BR1b, and BRIc and the cathode bridge electrode BR2 may include (e.g., be made of) a same material. For example, the first to third anode bridge electrodes BR1a, BR1b, and BRIc and the cathode bridge electrode BR2 may include at least one material selected from various types of conductive materials.

Referring to FIGS. 18 and 19, the first anode bridge electrode BR1a may extend from an insulating film 40 (LD1) (hereinafter referred to as a first insulating film) covering a side surface of an emission stack EST (LD1) of a first light-emitting element LD1 (hereinafter referred to as a first emission stack) to a first anode AE1 through the first anode connection electrode E1 (LD1) and an adhesive layer ADL. The first anode bridge electrode BR1a may expose an upper surface of the first emission stack EST (LD1).

The first anode bridge electrode BR1a may be in direct contact with a first side surface S1_AE1 (e.g., refer to FIG. 14) and a second side surface S2_AE2 (e.g., refer to FIG. 14) of the first anode AE1 which are exposed without being covered by the adhesive layer ADL. The first anode bridge electrode BR1a may be in direct contact with the first anode connection electrode E1 (LD1) on a side surface of the first emission stack EST (LD1). The first anode AE1 and the first anode connection electrode E1 (LD1) may be electrically connected through the first anode bridge electrode BR1a.

The second anode bridge electrode BR1b may extend from an insulating film 40 (LD2) (hereinafter referred to as a second insulating film) covering a side surface of an emission stack EST (LD2) of a second light-emitting element LD2 (hereinafter referred to as a second emission stack) to a second anode AE2 through the second anode connection electrode E1 (LD2) and the adhesive layer ADL. The second anode bridge electrode BR1b may expose an upper surface of the second emission stack EST (LD2).

The second anode bridge electrode BR1b may be in direct contact with a first side surface S1_AE2 (e.g., refer to FIG. 14) and a second side surface S2_AE2 (e.g., refer to FIG. 14) of the second anode AE2 which are exposed without being covered by the adhesive layer ADL. The second anode bridge electrode BR1b may be in direct contact with the second anode connection electrode E1 (LD2) on a side surface of the second emission stack EST (LD2) of the second light-emitting element LD2. The second anode AE2 and the second anode connection electrode E1 (LD2) may be electrically connected through the second anode bridge electrode BR1b.

The third anode bridge electrode BR1c may extend from an insulating film 40 (LD3) (hereinafter referred to as a third insulating film) covering a side surface of an emission stack EST (LD3) of the third light-emitting element LD3 (hereinafter referred to as a third emission stack) to the third anode AE3 through the third anode connection electrode E1 (LD3) and the adhesive layer ADL. The third anode bridge electrode BRIc may expose an upper surface of the third emission stack EST (LD3).

The third anode bridge electrode BRIc may be in direct contact with a first side surface S1_AE3 (e.g., refer to FIG. 14) and a second side surface S2_AE3 (e.g., refer to FIG. 14) of the third anode AE3 which are exposed without being covered by the adhesive layer ADL. The third anode bridge electrode BRIc may be in direct contact with the third anode connection electrode E1 (LD3) on a side surface of the third emission stack EST (LD3) of the third light-emitting element LD3. The third anode AE3 and the third anode connection electrode E1 (LD3) may be electrically connected to each other through the third anode bridge electrode BR1c.

Referring to FIGS. 18 and 20, the cathode bridge electrode BR2 may extend from the adhesive layer ADL covering an upper surface of the cathode CE to first to third insulating films 40 (LD1), 40 (LD2), and 40 (LD3) covering side surfaces of the first to third emission stacks EST (LD1), EST (LD2), and EST (LD3) through the first to third cathode connection electrodes E2 (LD1), E2 (LD2), and E2 (LD3). The cathode bridge electrode BR2 may expose the upper surfaces of the first to third emission stacks EST (LD1), EST (LD2), and EST (LD3). The cathode bridge electrode BR2 may be in direct contact with the first to third cathode connection electrodes E2 (LD1), E2 (LD2), and E2 (LD3).

Referring to FIGS. 18 and 21, the cathode bridge electrode BR2 may be in direct contact with the upper surface of the cathode CE which is exposed without being covered by the adhesive layer ADL. Accordingly, the cathode CE and the first to third cathode connection electrodes E2 (LD1), E2 (LD2), and E2 (LD3) may be electrically connected through the cathode bridge electrode BR2.

The first anode bridge electrode BR1a may be direct contact with an upper surface of the first anode AE1 which is exposed without being covered by the adhesive layer ADL. For example, the first anode bridge electrode BR1a may be in direct contact with an upper surface of the cathode CE adjacent to a second side surface S2_CE (e.g., refer to FIG. 16) of the cathode CE. Accordingly, the first anode AE1 and the first anode connection electrode E1 (LD1) may be electrically connected through the first anode bridge electrode BR1a.

Cross-sectional shapes of areas, in which the second and third light-emitting elements LD2 and LD3 are disposed, not shown, may be substantially the same as (similar to) a cross-sectional shape of an area, in which the first light-emitting element LD1 is disposed, shown in FIG. 18.

For example, the second anode bridge electrode BR1b may be in direct contact with an upper surface of the second anode AE2 which is exposed without being covered by the adhesive layer ADL. For example, the third anode bridge electrode BR1c may be in direct contact with an upper surface of the third anode AE3 which is exposed without being covered by the adhesive layer ADL. Thus, detailed description of the same or similar constituent elements is omitted.

Referring to FIGS. 18 and 22, the cathode bridge electrode BR2 may be disposed on the adhesive layer ADL covering the first side surface S1_CE of the cathode CE. The cathode bridge electrode BR2 may be in direct contact with the upper surface of the cathode CE which is exposed without being covered by the adhesive layer ADL.

Referring to FIGS. 19 to 22, the first to third anode bridge electrodes BR1a, BR1b, and BR1c and the cathode bridge electrode BR2 may not be in direct contact with a planarization layer PLA.

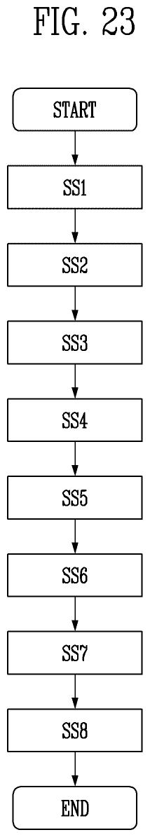

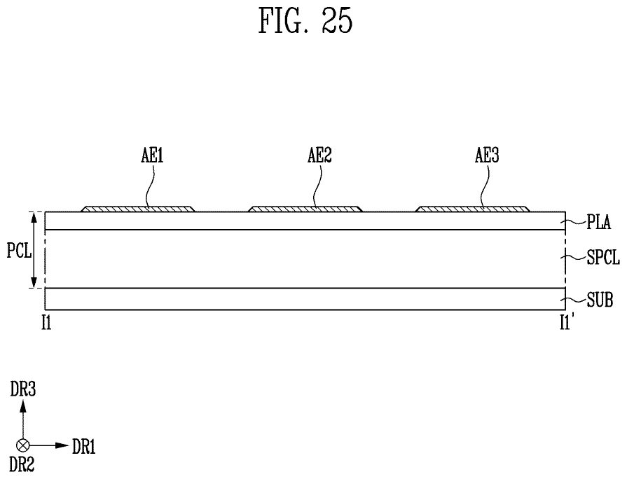

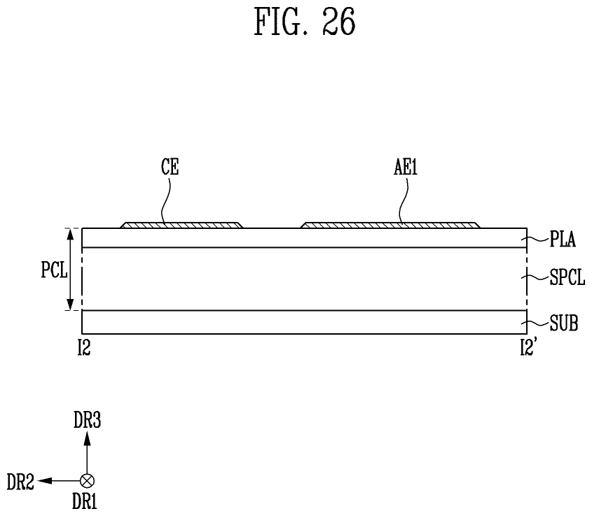

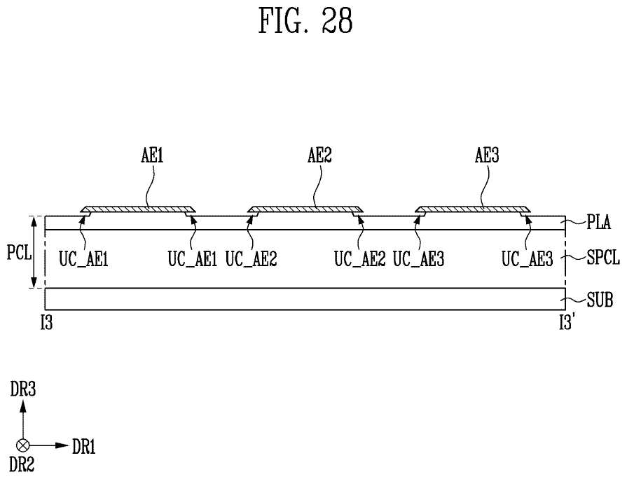

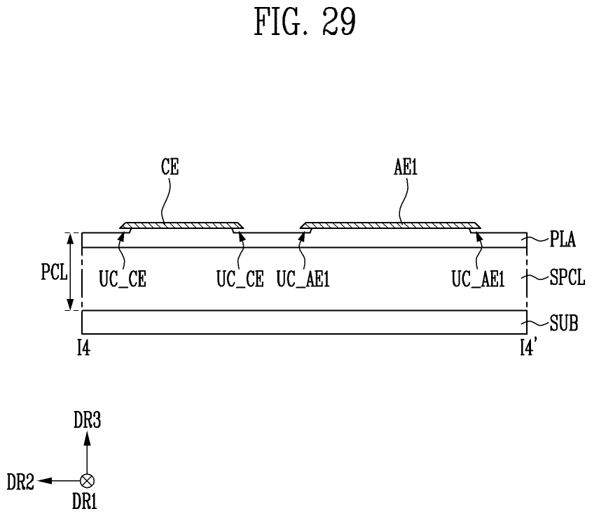

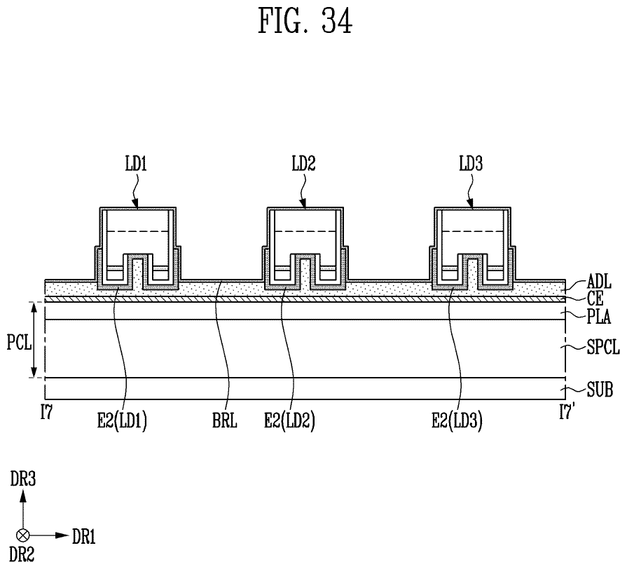

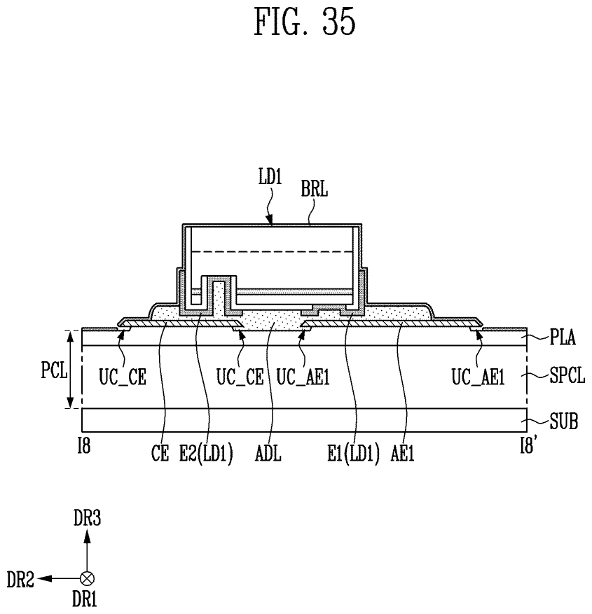

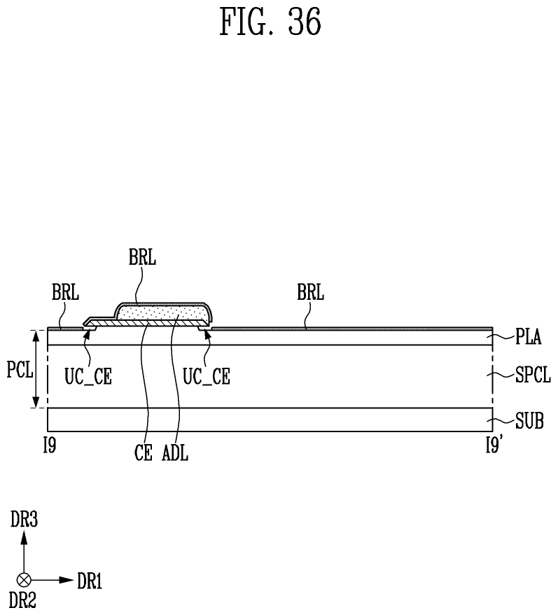

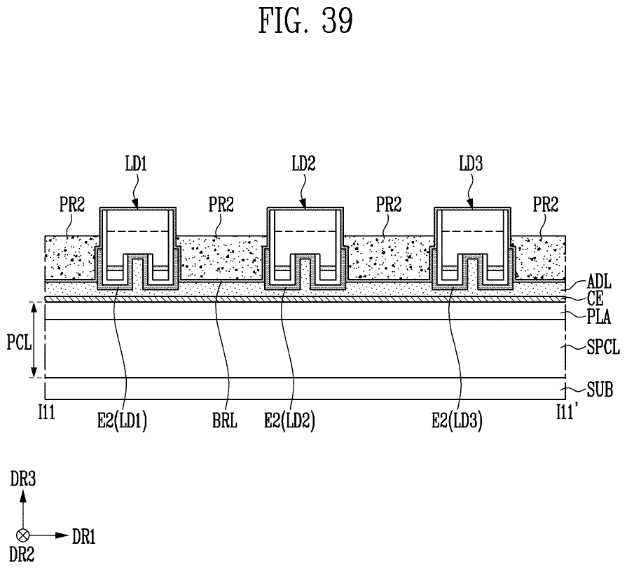

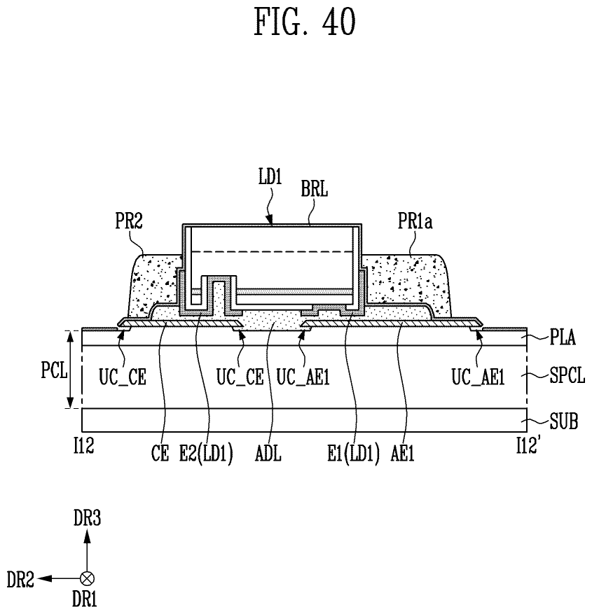

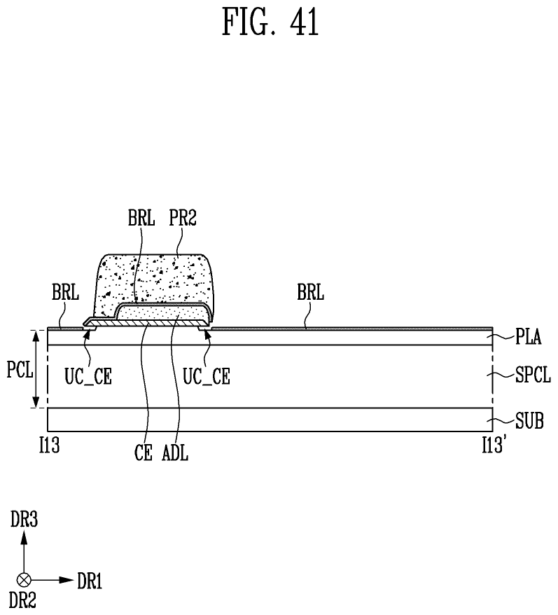

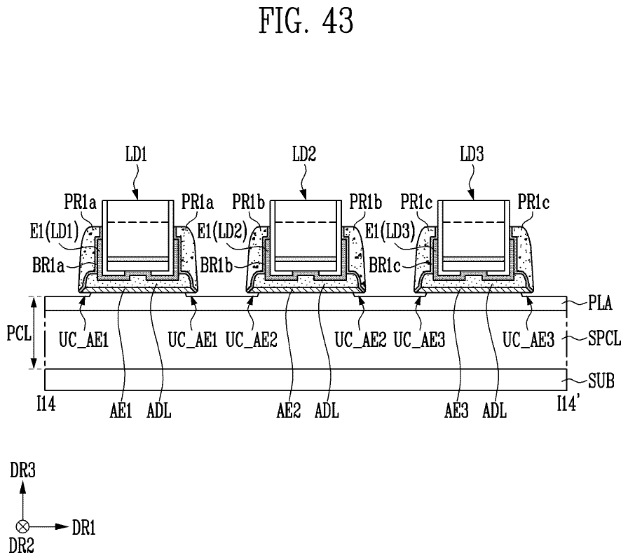

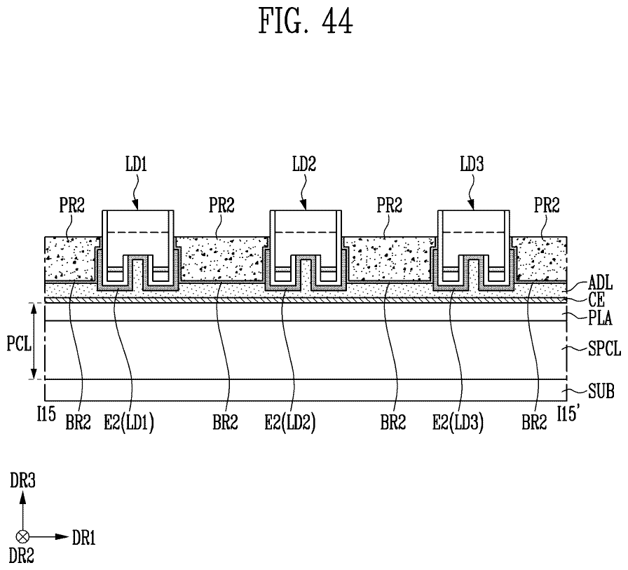

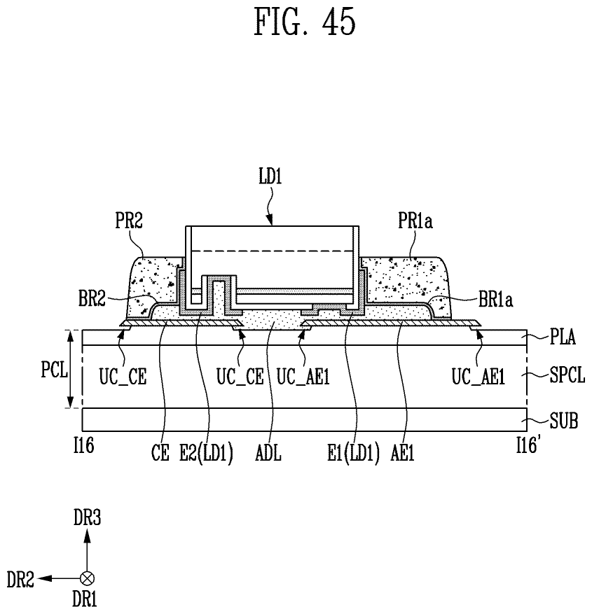

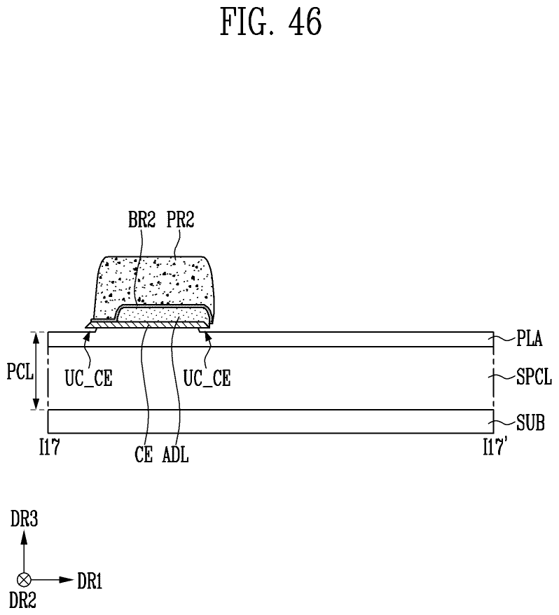

FIGS. 23 to 47 are schematic views for describing a method of manufacturing a display device including the pixel of FIGS. 10 to 22. Hereinafter, detained description of the same or similar constituent elements is omitted.

Referring to FIG. 23, a method of manufacturing a display device DD may include first to eighth operations SS1, SS2, SS3, SS4, SS5, SS6, SS7, and SS8.

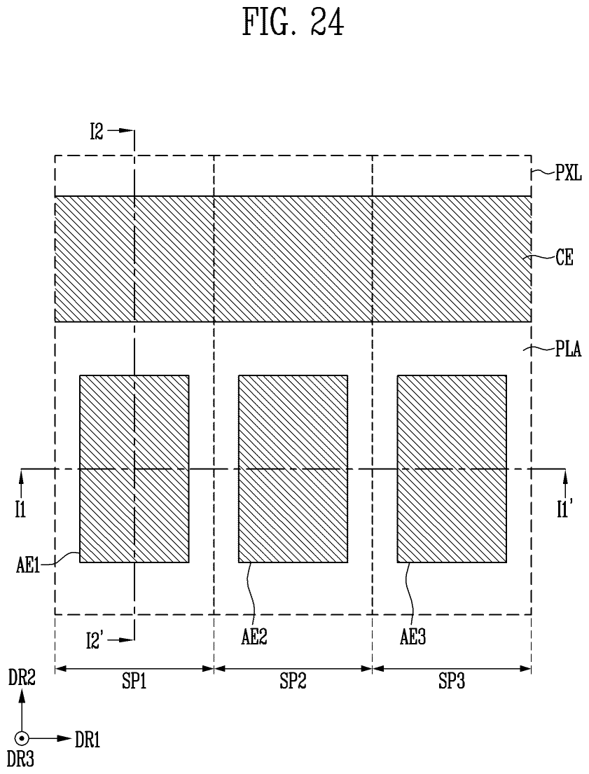

Referring to FIGS. 24 to 26, a first anode AE1, a second anode AE2, a third anode AE3, and a cathode CE may be formed on a planarization layer PLA (SS1).

In the operation (SS1), an upper surface of the planarization layer PLA may be substantially flat. The first to third anodes AE1, AE2, and AE3 may be spaced apart from each other and may be respectively electrically connected to a first subpixel circuit, a second subpixel circuit, and a third subpixel circuit included in a pixel circuit layer PCL. The cathode CE may be spaced apart from the first to third anodes AE1, AE2, and AE3.

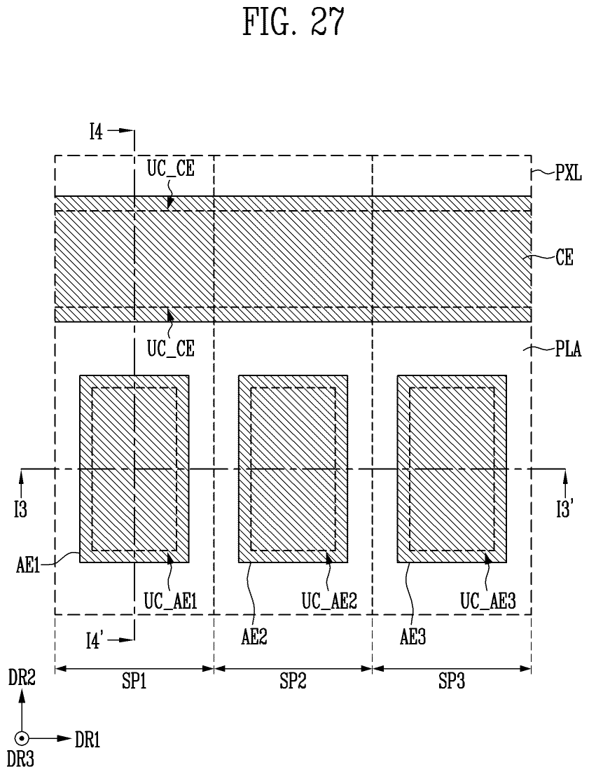

Referring to FIGS. 27 to 29, a first anode undercut UC_AE1, a second anode undercut UC_AE2, a third anode undercut UC_AE3, and a cathode undercut UC_CE may be formed in the planarization layer PLA (SS2).

In the operation (SS2), the first to third anodes AE1, AE2, and AE3 and the cathode CE may be (e.g., be used as) a mask to perform ashing on the planarization layer PLA. Thus, the first to third anode undercuts UC_AE1, UC_AE2, and UC_AE3 and the cathode undercut UC_CE may be formed. The ashing may be performed using, for example, oxygen plasma using an O2 gas.

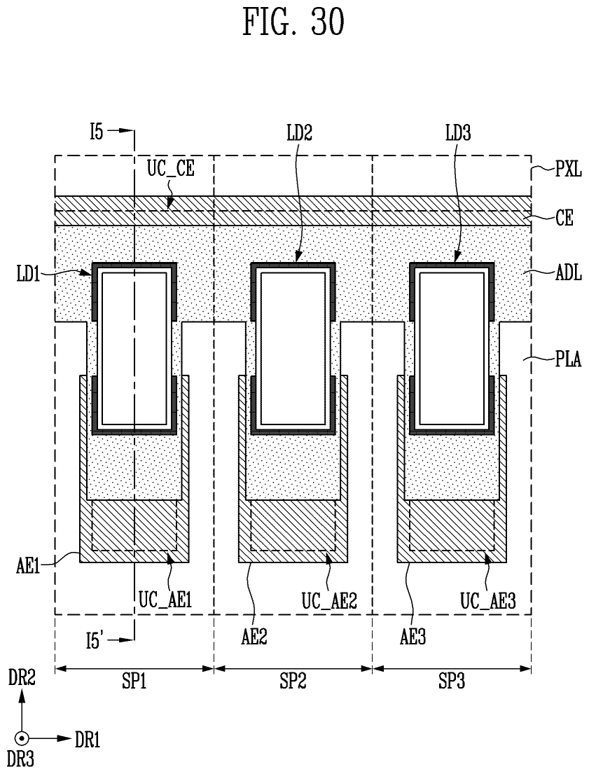

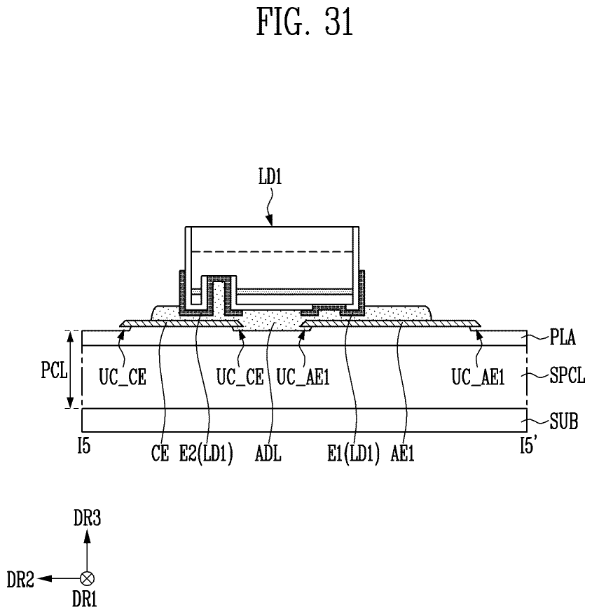

Referring to FIGS. 30 and 31, an adhesive layer ADL may be formed on the first to third anodes AE1, AE2, and AE3 and the cathode CE (SS3), and a first light-emitting element LD1, a second light-emitting element LD2, and a third light-emitting element LD3 may be disposed on the adhesive layer ADL (SS4).

In the operations (SS3 and SS4), the first to third light-emitting elements LD1, LD2, and LD3 may be fixed at positions (e.g., preset or selectable positions) by the adhesive layer ADL.

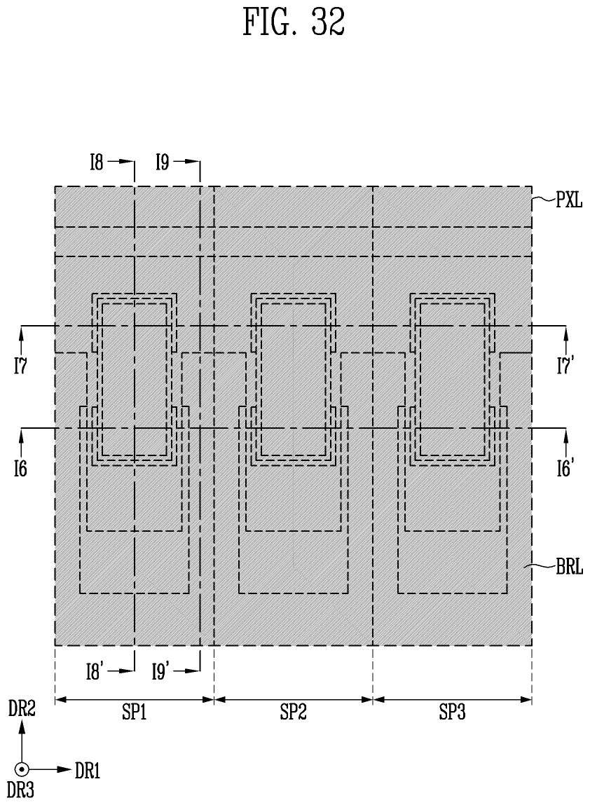

Referring to FIGS. 32 to 36, a bridge electrode layer BRL may be deposited on a surface (e.g., the entire surface of the elements such as the first to third light-emitting elements LD1, LD2, and LD3, the adhesive layer ADL, the first to third anodes AE1, AE2, and AE3, the cathode CD, or the like shown in FIGS. 30 and 31) (SS5).

In the operation (SS5), at least a portion of the bridge electrode layer BRL deposited on the entire surface may be electrically disconnected by the first to third anode undercuts UC_AE1, UC_AE2, and UC_AE3 and the cathode undercut UC_CE.

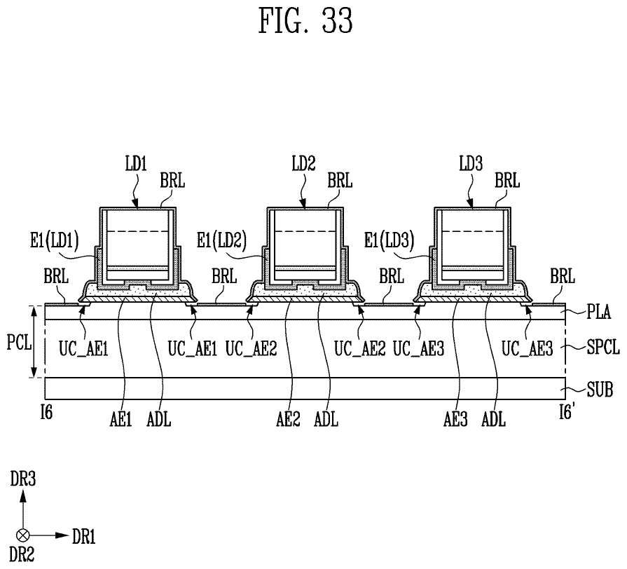

For example, as shown in FIGS. 33, 35, and 36, in areas that do not overlap the adhesive layer AD in a plan view, at least a portion of the bridge electrode layer BRL may be electrically disconnected by the first to third anode undercuts UC_AE1, UC_AE2, and UC_AE3 and the cathode undercuts UC_CE. The first to third anode undercuts UC_AE1, UC_AE2, and UC_AE3 and the cathode undercut UC_CE may disconnect at least a portion of the bridge electrode layer BRL deposited on the entire surface.

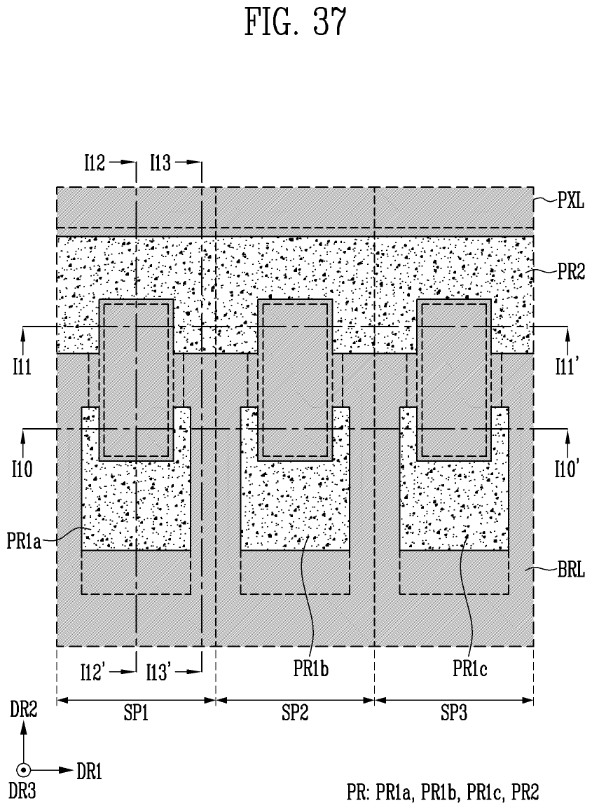

Referring to FIGS. 37 to 41, a photoresist pattern layer PR may be formed (SS6).

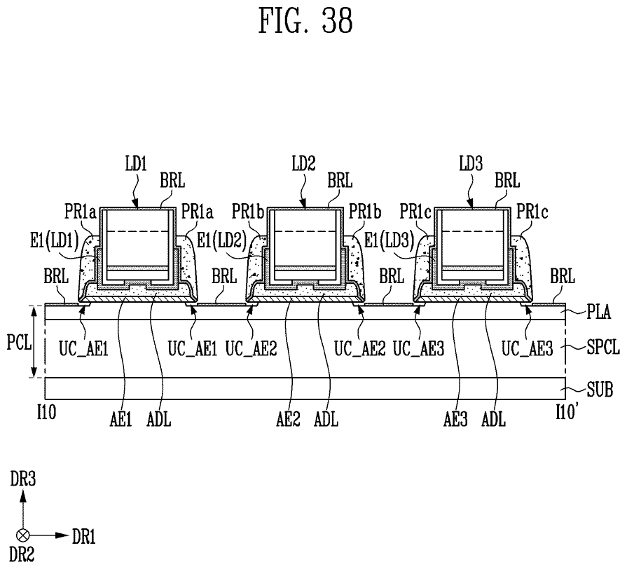

The photoresist pattern layer PR may include a 1-1 photoresist pattern PRla having a planar shape corresponding to a planar shape of a first anode bridge electrode BR1a, a 1-2 photoresist pattern PR1b having a planar shape corresponding to a planar shape of a second anode bridge electrode BR1b, a 1-3 photoresist pattern PRIc having a planar shape corresponding to a planar shape of a third anode bridge electrode BR1c, and a second photoresist pattern PR2 having a planar shape corresponding to a planar shape of a cathode bridge electrode BR2. As shown in FIGS. 38 to 40, the first to third light-emitting elements LD1, LD2, and LD3 may partially protrude above the photoresist pattern layer PR.

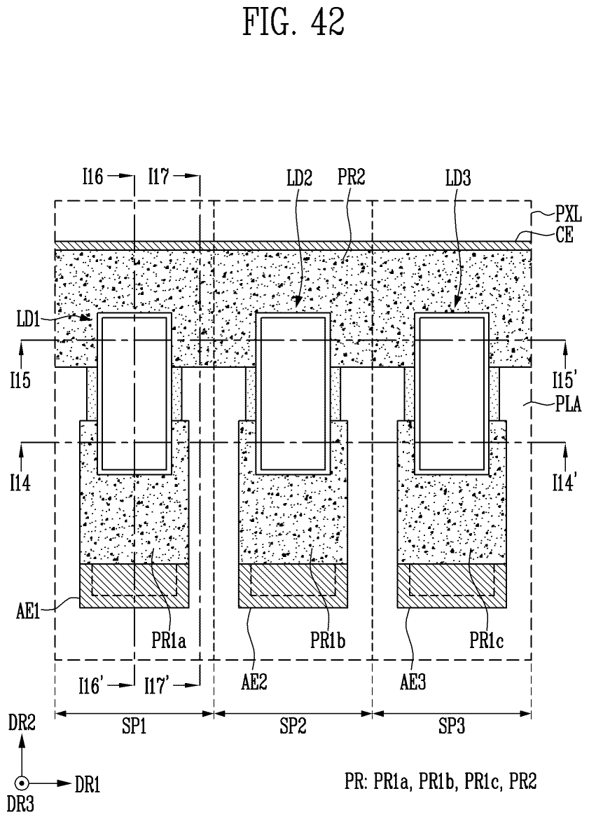

Referring to FIGS. 42 to 46, the bridge electrode layer BRL may be etched (e.g., partially etched) using the photoresist pattern layer PR as a mask (SS7).

In the operation (SS7), a portion of the bridge electrode layer BRL may be removed through etching. The remaining portion of the bridge electrode layer BRL may form the first to third anode bridge electrodes BR1a, BR1b, and BR1c and the cathode bridge electrode BR2.

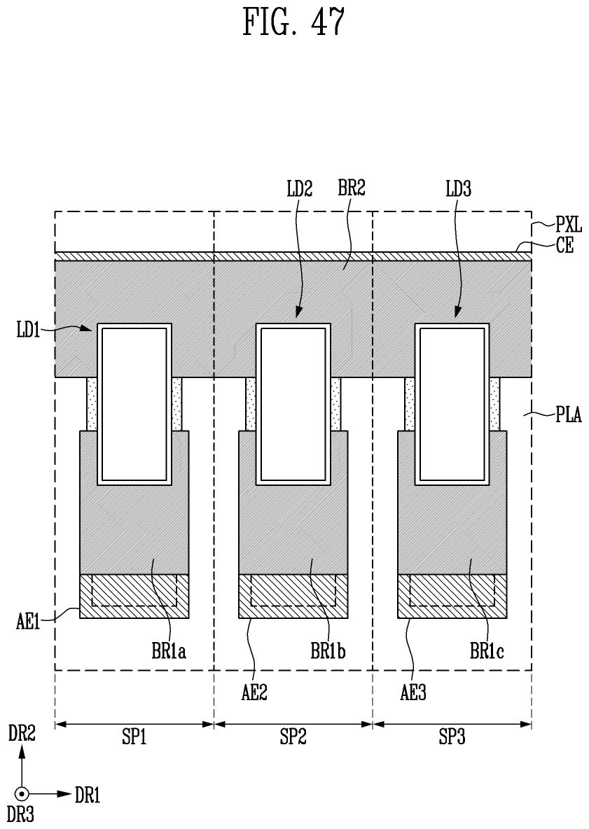

Referring to FIG. 47, the photoresist pattern layer PR may be removed (SS8). Accordingly, the display device DD including the pixels PXL described with reference to FIGS. 10 to 22 may be provided.

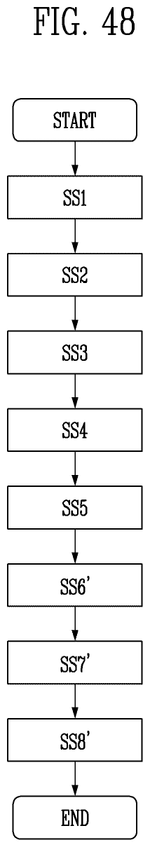

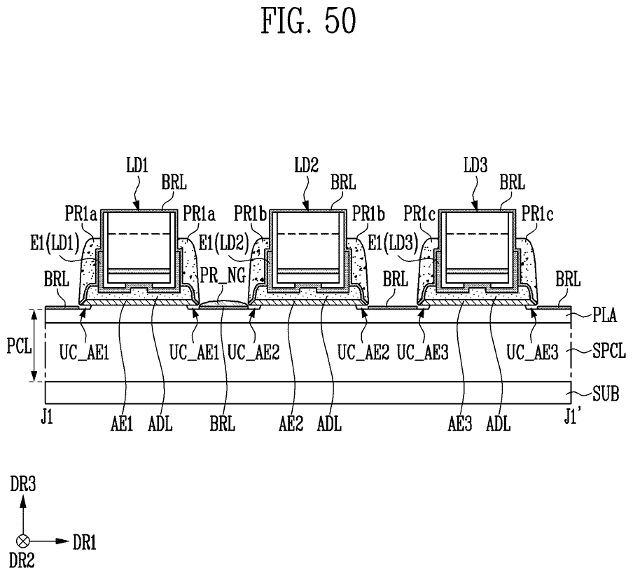

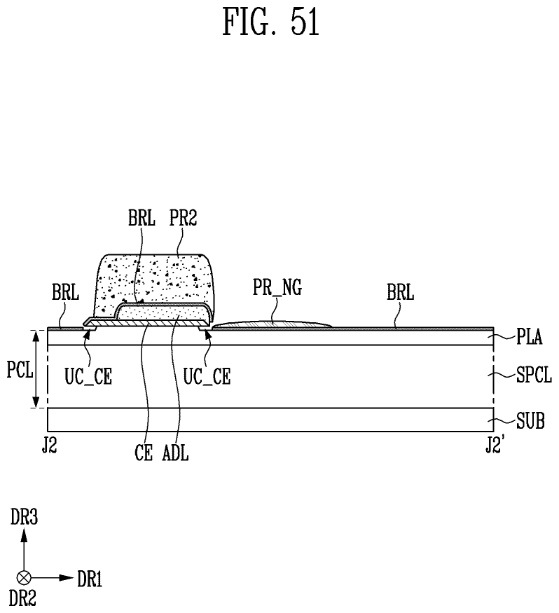

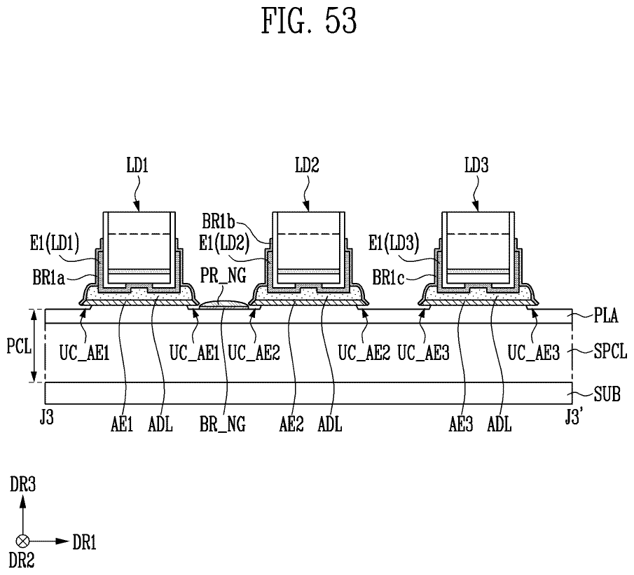

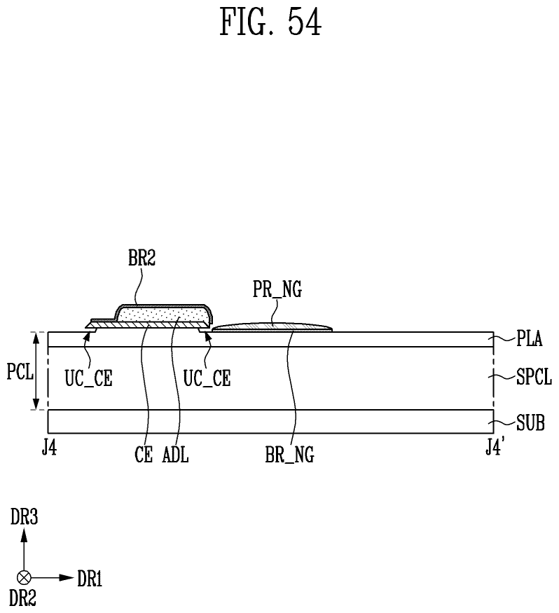

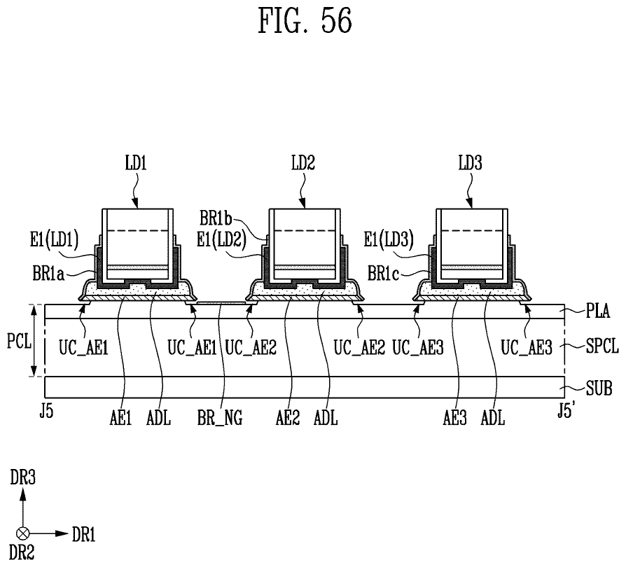

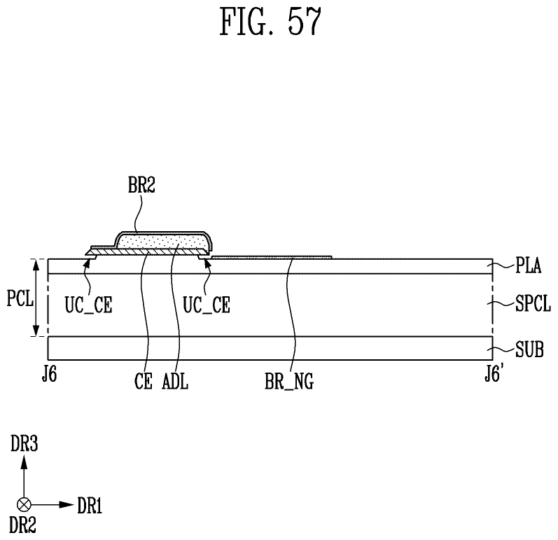

FIGS. 48 to 57 are schematic views for describing an embodiment in which residues of a photoresist pattern layer are generated.

Referring to FIG. 48, a method of manufacturing a display device DD may include first to eighth operations SS1, SS2, SS3, SS4, SS5, SS6′, SS7′, and SS8′. Referring to FIG. 48, the method of manufacturing the display device DD is different from the method of manufacturing the display device with reference to FIGS. 23 to 36 at least in the sixth operation SS6′ and the seventh operation SS7′. Therefore, detained description of the same or similar constituent elements is omitted.

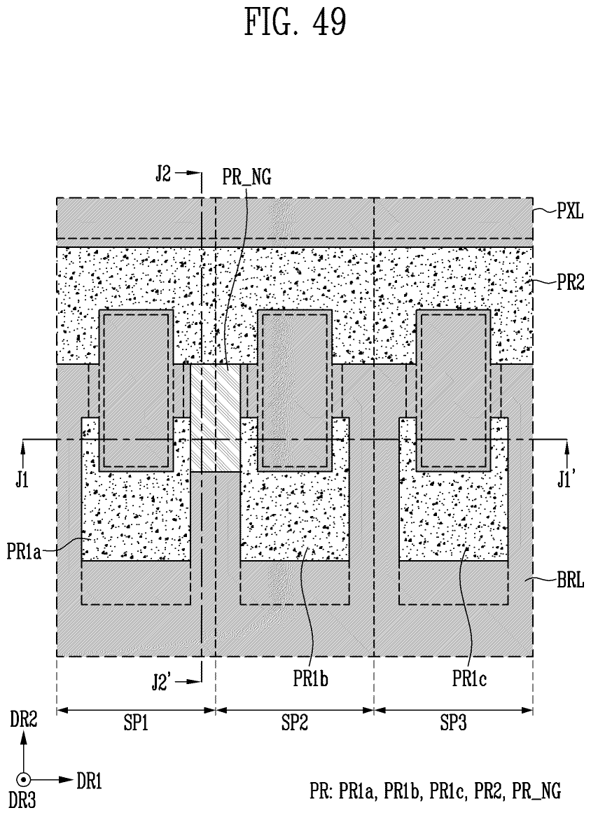

Referring to FIGS. 49 to 51, a photoresist pattern layer PR may be formed (SS6′).

In the operation (SS6′), the photoresist pattern layer PR may further include a residual photoresist pattern PR_NG unlike that described with reference to FIGS. 37 to 41. The residual photoresist pattern PR_NG may be formed, for example, in case that a valley (e.g., a portion of a valley) between a first light-emitting element LD1 and a second light-emitting element LD2 is not sufficiently exposed to light. However, the disclosure is not limited thereto, and the residue photoresist pattern PR_NG may be formed for various reasons during a process. The residual photoresist pattern PR_NG may cover a portion of a bridge electrode layer BRL that is disposed (e.g., directly disposed) on a planarization layer PLA.

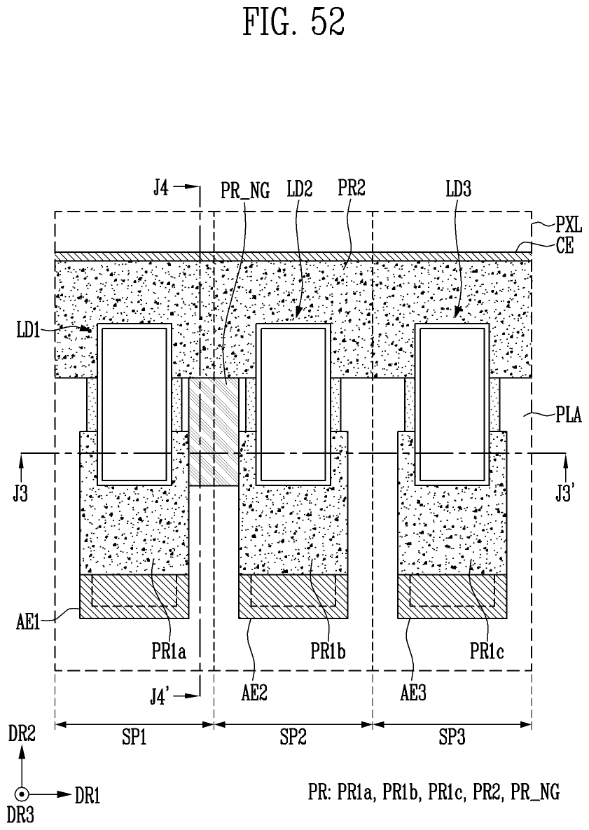

Referring to FIGS. 52 to 54, the bridge electrode layer BRL may be etched (e.g., partially etched) using the photoresist pattern layer PR as a mask (SS7′).

In the operation (SS7′), a portion of the bridge electrode layer BRL may be removed through etching. A portion of the bridge electrode layer BRL covered by the residual photoresist pattern PR_NG may form a residual bridge electrode BR_NG without being removed through etching.

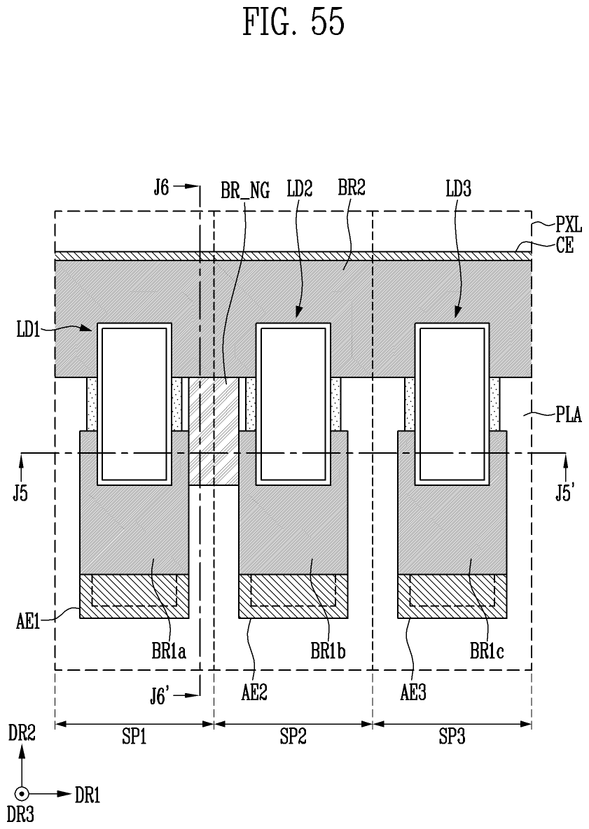

Referring to FIGS. 55 to 57, the photoresist pattern layer PR may be removed (SS8′). Accordingly, the pixel PXL described with reference to FIGS. 10 to 22 may further include the residual bridge electrode BR_NG.

Referring again to FIGS. 49 to 57, in an operation (for example, SS5, see FIGS. 32 to 36) prior to operation SS6′ of forming the photoresist pattern layer PR, the bridge electrode layer BRL may be partially disconnected by first to third anode undercuts UC_AE1, UC_AE2, and UC_AE3 and a cathode undercut UC_CE. A portion of the bridge electrode layer BRL covered by the residue photoresist pattern PR_NG, that is, the residue bridge electrode BR_NG, may be separated from first to third anode bridge electrodes BR1a, BR1b, and BR1c, first to third anodes AE1, AE2, and AE3, a cathode bridge electrode BR2, and a cathode CE by the first to third anode undercuts UC_AE1, UC_AE2, and UC_AE3 and the cathode undercut UC_CE. Therefore, even when the residual bridge electrode BR_NG is formed, an electrical short circuit may not occur between the first to third anode bridge electrodes BR1a, BR1b, and BR1c, the first to third anodes AE1, AE2, and AE3, the cathode bridge electrode BR2, and the cathode CE through the residual bridge electrode BR_NG.

In the disclosure, by forming the first to third anode undercuts UC_AE1, UC_AE2, and UC_AE3 and the cathode undercut UC_CE, defects (for example, an electrical short circuit) caused by the residual photoresist patterns PR_NG formed for various reasons during a process may be prevented.

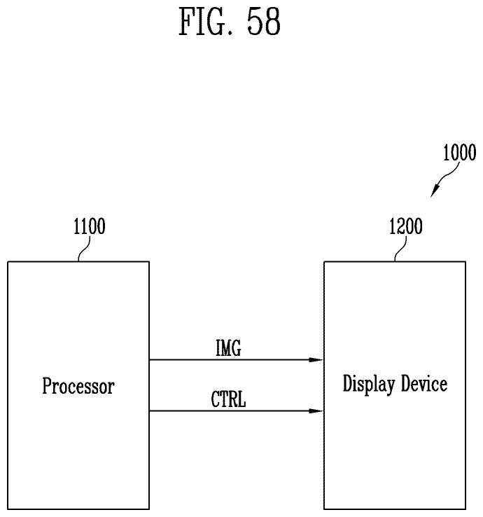

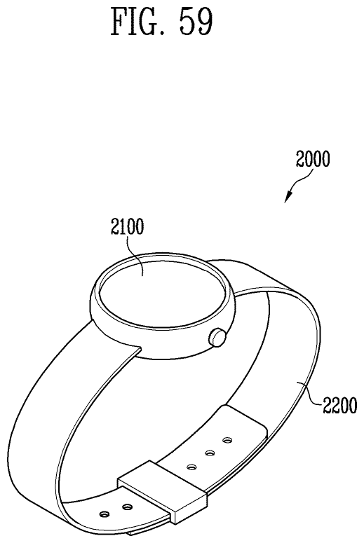

FIG. 58 is a schematic block diagram for describing a display system according to an embodiment.

Referring to FIG. 58, a display system (or electronic device) 1000 may include a processor 1100 and a display device 1200.

The processor 1100 may perform various tasks and calculations. In embodiments, the processor 1100 may include an application processor, a graphics processor, a microprocessor, a central processing unit (CPU), and the like. The processor 1100 may be electrically connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be the same as the display device DD described with reference to FIG. 1. The image data IMG and the control signal CTRL may be (e.g., be provided as) the input image data IMG and the control signal CTRL of FIG. 1, respectively.

The display system 1000 may include a computing system that displays an image. The display system 1000 may be included in various electronic apparatuses, and the electronic apparatuses may include at least one of a smart watch, a mobile phone, a smartphone, a portable computer, a tablet personal computer (PC), a watch phone, an automotive display, smart glasses, a portable multimedia player (PMP), a navigation device, an ultra-mobile personal computer (UMPC), or the like. The display system 1000 may include at least one of a head-mounted display (HMD) device, a VR device, an MR device, an AR device, or the like. The display device 1200 of the display system 1000 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a tablet computer, a phablet, a personal digital assistant (PDA), a wearable device, a laptop computer, a digital camera, a camcorder, a viewfinder, a micro display, a three-dimensional (3D) display, a vehicle, a video wall with multiple displays tiled together, a theater screen, a stadium screen, a phototherapy device, or a signboard.

FIGS. 59 to 62 are schematic perspective views for describing application examples of the display system of FIG. 58.

Referring to FIG. 59, the display system 1000 of FIG. 58 may be applied to a smart watch 2000 including a display part 2100 and a strap part 2200.

The smart watch 2000 may be a wearable electronic device. For example, the smart watch 2000 may have a structure in which the strap part 2200 is mounted on a user's wrist. For example, the display system 1000 (e.g., refer to FIG. 58) and/or the display device 1200 (e.g., refer to FIG. 58) may be applied to the display part 2100, and image data including time information may be provided to a user.

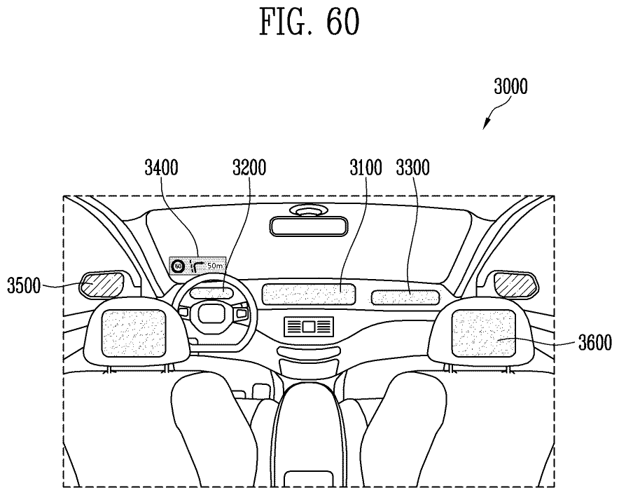

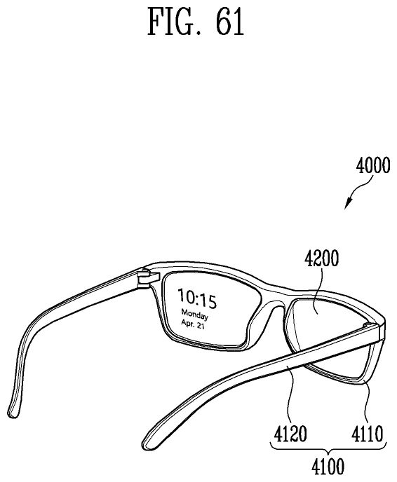

Referring to FIG. 60, the display system 1000 of FIG. 58 may be applied to an automotive display system 3000. For example, the automotive display system 3000 may include a computing system provided inside and/or outside a vehicle to provide image data.

For example, the display system 1000 (e.g., refer to FIG. 58) and/or the display device 1200 (e.g., refer to FIG. 58) may be applied to at least one of an infotainment panel 3100, a cluster 3200, a co-driver display 3300, a head-up display 3400, a side mirror display 3500, and a rear-seat display 3600 which are provided in a vehicle.

Referring to FIG. 61, the display system 1000 of FIG. 58 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a leg part 4120 worn by a user. The leg part 4120 may be connected to the housing 4110 through a hinge and may be folded or unfolded relative to the housing 4110.

A battery, a touch pad, a microphone, a camera, or the like may be embedded (or included) in the frame 4100. A projector that outputs light, a processor that controls light signals, or the like may be embedded (or included) in the frame 4100.

The lens part 4200 may include an optical member that transmits or reflects light. For example, the lens part 4200 may include glass, a transparent synthetic resin, or the like.

In order for user's eyes to perceive visual information, the lens part 4200 mat reflect an image by an optical signal transmitted from the projector of the frame 4100 through a rear surface of the lens part 4200 (for example, a surface facing the user's eyes). For example, a user may perceive visual information such as time or date displayed on the lens part 4200. The projector and/or the lens part 4200 may be a type of a display device. The display device 1200 may be applied to the projector and/or the lens part 4200.

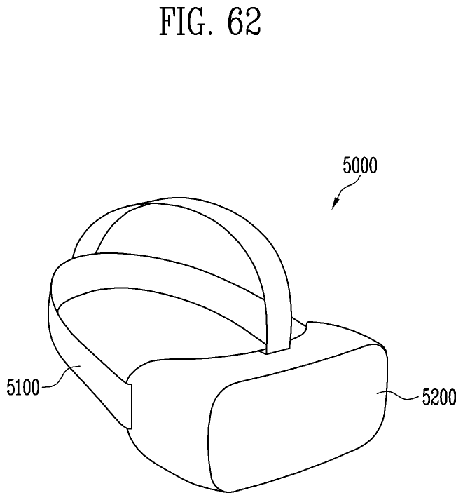

Referring to FIG. 62, the display system 1000 of FIG. 58 may be applied to a head-mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mounted band 5100 and a display device accommodation case 5200. The head-mounted band 5100 may be connected to the display device accommodation case 5200. The head-mounted band 5100 may include a horizontal band and/or a vertical band which are for fixing the head-mounted display device 5000 to the user's head. The horizontal band may be adjacent to (e.g., surround) a side portion of the user's head, and the vertical band may be adjacent to (e.g., surround) an upper portion of the user's head. However, embodiments are not limited thereto. For example, the head-mounted band 5100 may be implemented in the form of a glasses frame, a helmet, or the like.

The display device accommodation case 5200 may accommodate the display system 1000 (e.g., refer to FIG. 58) and/or the display device 1200 (e.g., refer to FIG. 58).

According to a display device according to embodiments of the disclosure, a planarization layer forming an uppermost layer of a pixel circuit layer may include a first anode undercut formed along an edge of a first anode in a plan view between the planarization layer and a lower surface of the first anode, and a cathode undercut formed along an edge of a cathode in a plan view between the planarization layer and a lower surface of the cathode.

In a process of forming a first anode bridge electrode and a cathode bridge electrode, the first anode undercut and the cathode undercut may prevent an electrical short circuit between the first anode bridge electrode, the first anode, the cathode bridge electrode, and the cathode due to a residue bridge electrode formed by unintended residues of a photoresist pattern. Accordingly, the reliability of a display device may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a cathode disposed on a pixel circuit layer and extending in a first direction;
a first anode disposed on the pixel circuit layer and spaced apart from the cathode in a second direction intersecting the first direction;
a first light-emitting element including:
a first emission stack;
a first anode connection electrode electrically connected to an area of the first emission stack; and
a first cathode connection electrode electrically connected to another area of the first emission stack;
an adhesive layer disposed between the first anode and the first anode connection electrode and between the cathode and the first cathode connection electrode;
a first anode bridge electrode in direct contact with the first anode and the first anode connection electrode; and
a cathode bridge electrode in direct contact with the cathode and the first cathode connection electrode,
wherein a planarization layer forming an uppermost layer of the pixel circuit layer includes:
a first anode undercut formed along an edge of the first anode in a plan view between the planarization layer and a lower surface of the first anode; and
a cathode undercut formed along an edge of the cathode in a plan view between the planarization layer and a lower surface of the cathode.

2. The display device of claim 1, wherein the adhesive layer completely covers a side surface facing the first anode among side surfaces of the cathode.

3. The display device of claim 2, wherein the adhesive layer exposes another side surface opposite to the side surface among the side surfaces of the cathode.

4. The display device of claim 3, wherein the adhesive layer covers an upper surface of the cathode adjacent to the side surface of the cathode and exposes an upper surface of the cathode adjacent to the another side surface of the cathode.

5. The display device of claim 4, wherein the cathode bridge electrode is in direct contact with the upper surface of the cathode adjacent to the another side surface of the cathode.

6. The display device of claim 1, further comprising:
a second anode disposed on the pixel circuit layer, spaced apart from the cathode in the second direction, and spaced apart from the first anode in the first direction;
a second light-emitting element including:
a second emission stack;
a second anode connection electrode electrically connected to an area of the second emission stack; and
a second cathode connection electrode electrically connected to another area of the second emission stack; and
a second anode bridge electrode in direct contact with the second anode and the second anode connection electrode, wherein
the planarization layer further includes a second anode undercut formed along an edge of the second anode in a plan view between the planarization layer and a lower surface of the second anode.

7. The display device of claim 6, wherein the cathode bridge electrode is in direct contact with the second cathode connection electrode.

8. The display device of claim 6, wherein the adhesive layer exposes a side surface facing the second anode among side surfaces of the first anode.

9. The display device of claim 8, wherein the first anode bridge electrode is in direct contact with at least a portion of the side surface of the first anode.

10. The display device of claim 8, wherein the adhesive layer exposes another side surface opposite to the side surface among the side surfaces of the first anode.

11. The display device of claim 10, wherein the first anode bridge electrode is in direct contact with at least a portion of the another side surface of the first anode.

12. The display device of claim 6, wherein the adhesive layer exposes a side surface facing the first anode among side surfaces of the second anode.

13. The display device of claim 12, wherein the second anode bridge electrode is in direct contact with at least a portion of the side surface of the second anode.

14. The display device of claim 12, wherein the adhesive layer exposes another side surface opposite to the side surface among the side surfaces of the second anode.

15. The display device of claim 14, wherein the second anode bridge electrode is in direct contact with at least a portion of the another side surface of the second anode.

16. A method of manufacturing a display device, the method comprising:
forming a cathode and a first anode, which are spaced apart from each other, on a planarization layer forming an uppermost layer of a pixel circuit layer;
forming a first anode undercut and a cathode undercut in the planarization layer;
forming an adhesive layer on the first anode and the cathode;
arranging a first light-emitting element on the adhesive layer, the first light-emitting element including:
a first emission stack;
a first anode connection electrode electrically connected to an area of the first emission stack; and
a first cathode connection electrode electrically connected to another area of the first emission stack; and
forming a bridge electrode including:
a first anode bridge electrode electrically connecting the first anode and the first anode connection electrode; and
a cathode bridge electrode electrically connecting the cathode and the first cathode connection electrode, wherein
the first anode undercut is formed along an edge of the first anode in a plan view between the planarization layer and a lower surface of the first anode, and
the cathode undercut is formed along an edge of the cathode in a plan view between the planarization layer and a lower surface of the cathode.

17. The method of claim 16, wherein the forming of the first anode undercut and the cathode undercut in the planarization layer includes ashing the planarization layer using the first anode and the cathode as a mask.

18. The method of claim 16, wherein the forming of the bridge electrode includes:
depositing a bridge electrode layer on upper surfaces of the first light-emitting element, the adhesive layer, the cathode, and the first anode;
forming a photoresist pattern layer corresponding to a shape of the first anode bridge electrode and a shape of the cathode bridge electrode;
etching the bridge electrode layer using the photoresist pattern layer as a mask; and
removing the photoresist pattern layer, wherein
at least a portion of the bridge electrode layer is electrically disconnected by the first anode undercut and the cathode undercut.

19. The method of claim 18, wherein the first light-emitting element partially protrudes above the photoresist pattern layer.

20. An electronic apparatus comprising:
a processor to provide image data; and
a display device to display an image based on the image data,
wherein the display device comprises:
a cathode disposed on a pixel circuit layer and extending in a first direction;
a first anode disposed on the pixel circuit layer and spaced apart from the cathode in a second direction intersecting the first direction;
a first light-emitting element including a first emission stack, a first anode connection electrode electrically connected to an area of the first emission stack, and a first cathode connection electrode electrically connected to another area of the first emission stack;
an adhesive layer disposed between the first anode and the first anode connection electrode and between the cathode and the first cathode connection electrode;
a first anode bridge electrode in direct contact with the first anode and the first anode connection electrode; and
a cathode bridge electrode in direct contact with the cathode and the first cathode connection electrode, and
a planarization layer forming an uppermost layer of the pixel circuit layer includes:
a first anode undercut formed along an edge of the first anode in a plan view between the planarization layer and a lower surface of the first anode; and
a cathode undercut formed along an edge of the cathode in a plan view between the planarization layer and a lower surface of the cathode.
